(19) United States
(12) Patent Application Publication
(10) Pub. No.: US 2012/0324302 A1
(43) Pub. Date: Dec. 20, 2012

(54) INTEGRATED CIRCUIT FOR TESTING USING A HIGH-SPEED INPUT/OUTPUT INTERFACE

(75) Inventors: Baris Arslan, La Jolla, CA (US); Michael Laisne, Encinitas, CA (US); George Alan Wiley, San Diego, CA (US); Geoffrey D. Shippee, Palo Alto, CA (US)

(73) Assignee: QUALCOMM INCORPORATED, San Diego, CA (US)

(21) Appl. No.: 13/426,235

(22) Filed: Mar. 21, 2012

Related U.S. Application Data
(60) Provisional application No. 61/498,431, filed on Jun. 17, 2011.

(51) Int. Cl. G01R 31/3177; G06F 11/25

(52) U.S. Cl. 714/727; 714/724; 714/733; 714/726; 714/E11.155

(57) ABSTRACT

An integrated circuit configured for testing is described. The integrated circuit includes a high-speed input/output interface. The integrated circuit also includes a test controller coupled to the high-speed input/output interface. The integrated circuit further includes test circuitry coupled to the test controller. The test controller controls the test circuitry based on controller protocol test information from the high-speed input/output interface.

### RELATED APPLICATIONS

This application is related to and claims priority from U.S. Provisional Patent Application Ser. No. 61/498,431 filed Jun. 17, 2011, for “FRAMEWORK AND PROTOCOL FOR UTILIZING HIGH-SPEED INPUT/OUTPUT INTERFACES FOR TEST CONTROL AND TEST DATA DELIVERY.”

### TECHNICAL FIELD

The present disclosure relates generally to electronic devices. More specifically, the present disclosure relates to an integrated circuit for testing using a high-speed input/output interface.

### BACKGROUND

Electronic devices have become a part of everyday life. Examples of electronic devices include integrated circuits, cellular telephones, smartphones, wireless modems, computers, digital music players, Global Positioning System (GPS) units, Personal Digital Assistants, gaming devices, etc. Electronic devices are now placed in everything from automobiles to housing locks. The complexity of electronic devices has increased dramatically in the last few years. For example, many electronic devices have one or more processors that help control the device, as well as a number of digital circuits to support the processor and other parts of the device.

This increased complexity has led to an increased need for testing that can test integrated circuits and/or digital systems. Testing may be used to verify or test various parts of devices, such as pieces of hardware, software or a combination of both.

However, testing integrated circuits requires testing resources, such as testing equipment and time to perform the testing. In some cases, performing certain tests on integrated circuits may be limited to a particular manufacturing stage and to a limited number of integrated circuits at a time. As can be observed from this discussion, systems and methods that help improve the accessibility and/or speed of testing may be beneficial.

### SUMMARY

An integrated circuit configured for testing is described. The integrated circuit includes a high-speed input/output interface. The integrated circuit also includes a test controller coupled to the high-speed input/output interface. The integrated circuit further includes test circuitry coupled to the test controller. The test controller controls the test circuitry based on controller protocol test information from the high-speed input/output interface. The test controller may be separate from the high-speed input/output interface.

The integrated circuit may also include a test access port coupled to the test controller and to the test circuitry. The high-speed input/output interface may format high-speed input/output protocol test information into the controller protocol test information. The test controller may format the controller protocol test information into joint test action group protocol test information that is provided to the test access port to control the test circuitry.

The test controller may format joint test action group protocol test results into controller protocol test results. The high-speed input/output interface may format the controller protocol test results into high-speed input/output protocol test results.

A test access port interface signal may be intercepted before the test access port. Test control and data signals provided by the test access port may be intercepted after the test access port.

The test controller may perform a test on a part of test circuitry that is not accessed through the test access port. The test circuitry may be a boundary scan register, a scan chain, a register and/or memory.

The controller protocol test information may include a reset message an instruction message and/or a data message. The controller protocol test information may include a test data input message, a test mode select message and/or a test data output message. The controller protocol test information may include a message that includes a target test access port state, an input/output field and data.

The high-speed input/output interface may be a universal serial bus (USB) interface. The high-speed input/output interface may be a mobile display digital interface (MDDI).

The controller protocol test information may be in a parallel format. The controller protocol test information may be in a serial format.

A method for testing an integrated circuit is also described. The method includes receiving high-speed input/output protocol test information at a high-speed input/output interface. The method also includes generating controller protocol test information based on the high-speed input/output protocol test information. The method further includes providing the controller protocol test information to a test controller. The method additionally includes controlling test circuitry based on the controller protocol test information from the high-speed input/output interface.

A computer-program product for testing an integrated circuit is also described. The computer-program product includes a non-transitory tangible computer-readable medium with instructions. The instructions include code for causing an electronic device to receive high-speed input/output protocol test information at a high-speed input/output interface. The instructions also include code for causing the electronic device to generate controller protocol test information based on the high-speed input/output protocol test information. The instructions further include code for causing the electronic device to provide the controller protocol test information to a test controller. The instructions additionally include code for causing the electronic device to control test circuitry based on the controller protocol test information from the high-speed input/output interface.

An apparatus for testing an integrated circuit is also described. The apparatus includes means for receiving high-speed input/output protocol test information. The apparatus also includes means for generating controller protocol test information based on the high-speed input/output protocol test information. The apparatus further includes means for providing the controller protocol test information. The apparatus additionally includes means for controlling test circuitry based on the controller protocol test information.

### BRIEF DESCRIPTION OF THE DRAWINGS

FIG. 1 is a block diagram illustrating one configuration of an integrated circuit for testing using a high-speed input/output (HSIO) interface;

FIG. 2 is a flow diagram illustrating one configuration of a method for testing using a high-speed input/output interface (HSIO);

FIG. 3 is a block diagram illustrating a more specific configuration of an integrated circuit for testing using a high-speed input/output (HSIO) interface;

FIG. 4 is a flow diagram illustrating a more specific configuration of a method for testing using a high-speed input/output interface (HSIO);

FIG. 5 is a block diagram illustrating one example of an integrated circuit in which testing using a high-speed input/output interface (HSIO) may be implemented;

FIG. 6 is a block diagram illustrating another example of an integrated circuit in which testing using a high-speed input/output interface (HSIO) may be implemented;

FIG. 7 is a block diagram illustrating another example of an integrated circuit in which testing using a high-speed input/output interface (HSIO) may be implemented;

FIG. 8 is a block diagram illustrating another example of an integrated circuit in which testing using a high-speed input/output interface (HSIO) may be implemented;

FIG. 9 is a block diagram illustrating another example of an integrated circuit in which testing using a high-speed input/output interface (HSIO) may be implemented;

FIG. 10 is a block diagram illustrating another example of an integrated circuit in which testing using a high-speed input/output interface (HSIO) may be implemented;

FIG. 11 is a diagram illustrating one example of a controller protocol that may be used in accordance with the systems and methods disclosed herein;

FIG. 12 is a diagram illustrating another example of a controller protocol that may be used in accordance with the systems and methods disclosed herein;

FIG. 13 is a diagram illustrating another example of a controller protocol that may be used in accordance with the systems and methods disclosed herein; and

FIG. 14 illustrates various components that may be utilized in an electronic device.

### DETAILED DESCRIPTION

Unless expressly limited by its context, the term “signal” is used herein to indicate any of its ordinary meanings, including a state of a memory location (or set of memory locations) as expressed on a wire, bus, or other transmission medium. Unless expressly limited by its context, the term “generating” is used herein to indicate any of its ordinary meanings, such as computing or otherwise producing. Unless expressly limited by its context, the term “calculating” is used herein to indicate any of its ordinary meanings, such as computing, evaluating, and/or selecting from a set of values. Unless expressly limited by its context, the term “obtaining” is used to indicate any of its ordinary meanings, such as calculating, deriving, receiving (e.g., from an external device), and/or retrieving (e.g., from an array of storage elements). Where the term “comprising” is used in the present description and claims, it does not exclude other elements or operations. The term “based on” (as in “A is based on B”) is used to indicate any of its ordinary meanings, including the cases (i) “based on at least” (e.g., “A is based on at least B”) and, if appropriate in the particular context, (ii) “equal to” (e.g., “A is equal to B”). Similarly, the term “in response to” is used to indicate any of its ordinary meanings, including “in response to at least.”

Unless indicated otherwise, any disclosure of an operation of an apparatus having a particular feature is also expressly intended to disclose a method having an analogous feature (and vice versa), and any disclosure of an operation of an apparatus according to a particular configuration is also expressly intended to disclose a method according to an analogous configuration (and vice versa). The term “configuration” may be used in reference to a method, apparatus, or system as indicated by its particular context. The terms “method,” “process,” “procedure,” and “technique” are used generically and interchangeably unless otherwise indicated by the particular context. The terms “apparatus” and “device” are also used generically and interchangeably unless otherwise indicated by the particular context. The terms “element” and “module” are typically used to indicate a portion of a greater configuration. Any incorporation by reference of a portion of a document shall also be understood to incorporate definitions of terms or variables that are referenced within the portion, where such definitions appear elsewhere in the document, as well as any figures referenced in the incorporated portion.

As used herein, the term “block/module” may be used to indicate that a particular element may be implemented in hardware, software or a combination of both. The term “coupled” and variations thereof may be used to indicate that one element is directly or indirectly connected to another element. For example, if a first element is coupled to a second element, the first element may be connected directly to the second element or may be indirectly connected to the second element through a third element.

Many different kinds of electronic devices may benefit from testing. Such devices include, but are not limited to, integrated circuits, cellular telephones, wireless modems, computers, digital music players, Global Positioning System (GPS) units, Personal Digital Assistants, gaming devices, etc. One group of devices includes those that may be used with wireless communication systems. As used herein, the term “wireless communication device” refers to an electronic device that may be used for voice and/or data communication over a wireless communication network. Examples of wireless communication devices include cellular phones, smartphones, handheld wireless devices, wireless modems, laptop computers, personal computers, etc. A wireless communication device may alternatively be referred to as an access terminal, a mobile terminal, a subscriber station, a remote station, a user terminal, a terminal, a subscriber unit, a user equipment, etc.

Often, integrated circuits or chips may possess a dedicated test interface that is used to control the test features and to send and receive test data. One example of a dedicated test interface is a test access port (TAP). A “test access port (TAP)” is described in several examples herein. However, it should be noted that any dedicated test interface may be used instead of a test access port (TAP) in these examples. Furthermore, the term “joint test action group (JTAG) protocol” is used in several examples herein. However, it should be noted that any protocol that may be used to communicate with a dedicated test interface may be used instead of a joint test action group (JTAG) protocol in these examples.

When integrated circuits are assembled in a board, the test interface access may be lost due to limited routing channels. This may result in blocking the control of test features and subsequently preventing the execution of some tests, such as interconnect testing between chips (on an integrated circuit, for instance). For example, in a cellular phone, there is room for only a few wires for carrying data between devices and to peripherals. This is even worse for clamshell type cellular phones where only a few wires can go from the lower clam shell to the upper clam shell. Due to the limited availability of wires, the test interfaces of chips in the phone may not be accessed and subsequently users may not use the existing test methodologies to test device connectivity and structural functionality.

The board space required for a dedicated test interface is typically provided by either paying the additional cost of more expensive board routing (which is usually not an option except for very high end cell phones and devices). Alternatively, a test feature may simply not be provided, which can result in millions of dollars in additional production costs as the result of not being able to quickly identify the source of defects and yield issues.

The systems and methods disclosed herein address this problem by utilizing a high-speed input/output (HSIO) interface (e.g., universal serial bus (USB), mobile display digital interface (MDDI), etc.) as a test interface. Since numerous HSIO interfaces often exist on integrated circuits already, the systems and methods disclosed herein may enable test control without incurring additional routing cost that may be required for supporting dedicated test interface access. The systems and methods disclosed herein may be advantageous in that tests may be performed more quickly through a high-speed input/output (HSIO) interface than through typical dedicated test interfaces. Furthermore, the systems and methods disclosed herein may allow for testing a larger number of integrated circuits at once, since fewer pins per integrated circuit may be used in testing.

Thus, one advantage of using an HSIO interface for testing is the delivery of high-speed test data through a small number of pins. This enables faster testing and improved levels of parallelism due to the use of a small number of pins, subsequently reducing test cost. In other words, test cost may be reduced by using an HSIO interface for testing by reducing the amount of time needed to test and/or increasing the number of devices (e.g., integrated circuits) that may be tested at a time. Additionally, using an HSIO interface for testing may allow testing even when access to a dedicated test interface is blocked.

In one configuration, a test controller may be implemented on an integrated circuit that communicates with a test device through a HSIO interface. The test controller may be implemented in hardware and/or software (by using an existing processor in a device or on the integrated circuit, for example). The test controller may generate test instructions that would be typically generated by a TAP by encoding the data delivered through the HSIO interface.

Examples of several possible configurations of the systems and methods disclosed herein are given hereafter. In one configuration, the test controller (implemented in hardware and/or software) communicates with (e.g., sends and/or receives information) an external device (e.g., a test device) through the HSIO interface. In this configuration, the test controller intercepts test control and data signals provided by a TAP and provides appropriate control and data values based on instructions it obtains from the HSIO interface. The test controller may also deliver test results or responses to the external device through the HSIO. In one example of this configuration, test control and/or test data signals may be intercepted after the TAP. In another example, the TAP interface signals may be intercepted before the TAP. In yet another example, the test control and/or test data signals may be intercepted at any point in the downstream logic.

In some configurations, the systems and methods disclosed herein may additionally support other tests that may not be possible through a TAP interface (which may be relatively slow compared to an HSIO interface). For example, a high-speed test data stream may be routed to memory on the integrated circuit by using the HSIO.

Additionally or alternatively, the systems and methods disclosed herein may be used to drive multiple scan channels and load and/or unload registers in parallel. For example, if an HSIO interface physical (PHY) layer is sending and receiving data to and/or from the test controller in a parallel format, it may be used to drive multiple scan chains.

Alternatively, if the data is arriving (at the test controller) as a high-speed serial stream, the data may be decoded into multiple scan channels. For example, an 80 megabits per second (Mbps) data stream may be used to drive four scan chains at 20 Mbps. In addition to the serial load of data to the registers, a parallel data load may also be supported in some configurations. In one example, a particular register is selected and the data is loaded in parallel through an HSIO interface. Similarly, the selected register data may be read (e.g., unloaded) in parallel. In one configuration, a parallel load of data to all registers may be enabled. Optionally, identical data may be loaded to all registers or a particular register may be loaded with test data while loading the rest of the registers with a user programmable data (such as all 0s, for example). A selected register may also be read in parallel in some configurations.

A test controller and an HSIO may communicate based on a protocol (e.g., a “controller protocol”). For example, a test controller may get a clock input from an HSIO PHY or from an internal source. A communication channel is opened between the test controller and the HSIO and they communicate with each other based on a protocol (e.g., a “controller protocol”). One configuration of the protocol only sends reset, instruction or data to the test controller. The test controller sets a TAP finite state machine (FSM) to idle state after reset. Based on whether the communication is instruction or data, the test controller traverses the complete required FSM sequence starting from an idle state, completes the instruction and returns to the idle state (thus waiting for any additional command). Similarly, information (e.g., data) may be output through the HSIO interface (when requested, for example).

In another configuration, cycle-by-cycle FSM control may be provided by delivering complete TAP interface signals through the HSIO interface using an encoding. In this protocol configuration, a test mode select (TMS) sequence to reach a target TAP state is initially delivered. Data write and/or read may be performed at this particular state by utilizing test data in (TDI) and/or test data out (TDO) instructions. A new state transition may then follow by sending a following test mode select (TMS) sequence.

In another configuration, a target state and the operation (e.g., write and/or read) at this particular state may be embedded in an instruction. The test controller may directly jump to the target state by using the encoded state information in the incoming instruction and perform data shift in or shift out.

The systems and methods disclosed herein may utilize an existing HSIO interface as a test interface. This may eliminate the need for a dedicated test interface (e.g., TAP). Therefore, the systems and methods disclosed herein may reduce a routing requirement and enable test and debug capabilities that would not be possible otherwise. Consequently, test quality may be increased and device debug time may be reduced without dedicated test interface access. All instructions associated with the TAP and potentially other test features may be embedded in an HSIO interface protocol.

Various configurations are now described with reference to the Figures, where like reference numbers may indicate functionally similar elements. The systems and methods as generally described and illustrated in the Figures herein could be arranged and designed in a wide variety of different configurations. Thus, the following more detailed description of several configurations, as represented in the Figures, is not intended to limit scope, as claimed, but is merely representative of the systems and methods.

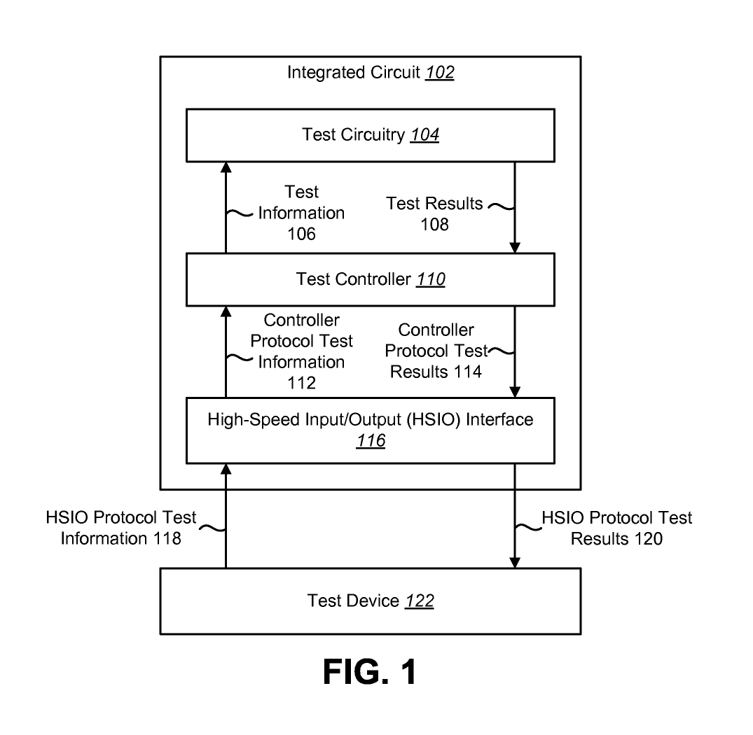

FIG. 1 is a block diagram illustrating one configuration of an integrated circuit 102 for testing using a high-speed input/output (HSIO) interface 116. The integrated circuit 102 includes test circuitry 104, a test controller 110 and a high-speed input/output (HSIO) interface 116. The high-speed input/output (HSIO) interface 116 may be coupled to the test controller 110 and the test controller 110 may be coupled to the test circuitry 104. The test circuitry 104 may comprise one or more circuit elements for testing. For example, the test circuitry 104 may include one or more discrete components (e.g., resistors, capacitors, inductors), diodes, transistors, latches, registers (e.g., boundary scan registers), scan chains, flip-flops, memory cells, buses, digital logic, processors, application-specific integrated circuits (ASICs), etc. In some configurations, the integrated circuit 102 may be considered a device under test (DUT). Additionally or alternatively, the test circuitry 104 may include circuitry for compressing and/or decompressing information for testing.

The test controller 110 may be used to control the test circuitry 104. For example, the test controller 110 may provide test information 106 (e.g., instructions, data, etc.) to the test circuitry 104 in order to perform one or more tests on the test circuitry 104. The test controller 110 may also receive test results 108 from the test circuitry 104. The test controller 110 may be implemented in hardware, software or a combination of both. For example, the test controller 110 may be implemented as an application-specific integrated circuit (ASIC), a microcontroller, a processor with instructions, etc. The test controller 110 may be coupled to the test circuitry 104 and to the high-speed input/output (HSIO) interface 116.

The high-speed input/output (HSIO) interface 116 may be used to receive information from another device and/or may be used to send (e.g., output) information to another device. The high-speed input/output (HSIO) interface 116 may include one or more physical ports, protocols and/or logic used to support the interface. Examples of the high-speed input/output (HSIO) interface 116 include universal serial bus (USB) interfaces, mobile display digital interfaces (MDDIs), Peripheral Component Interconnect Express (PCIe) interfaces, High-Definition Multimedia Interfaces (HDMI), Serial Advanced Technology Attachment (SATA) interfaces, Mobile Industry Processor Interface Display Serial Interfaces (MIPI DSI), Mobile Industry Processor Interface Camera Serial Interfaces (MIPI CSI), etc.

The high-speed input/output (HSIO) interface 116 may send controller protocol test information 112 to the test controller 110. The controller protocol test information 112 may include instructions and/or data that may be used for testing the test circuitry 104. The controller protocol test information 112 may conform to a controller protocol. In other words, the controller protocol test information 112 may be formatted according to a protocol used by the test controller 110. For instance, the controller protocol test information 112 may be structured according to particular message, frame, packet and/or timing structures as specified by the controller protocol.

The high-speed input/output (HSIO) interface 116 may receive controller protocol test results 114. The controller protocol test results 114 may include information (e.g., data) generated based on testing the test circuitry 104. The controller protocol test results 114 may be formatted according to the controller protocol. In other words, the controller protocol test results 114 may be formatted according to a protocol used by the test controller 110. For instance, the controller protocol test results 114 may be structured according to particular message, frame, packet and/or timing structures as specified by the controller protocol. Several examples of controller protocols are given in greater detail below. The high-speed input/output (HSIO) interface 116 may format the controller protocol test results 114 into HSIO protocol test results 120.

The high-speed input/output (HSIO) interface 116 may receive HSIO protocol test information 118 from a test device 122 and/or may send HSIO protocol test results 120 to the test device 122. However, it should be noted that the HSIO interface 116 may be used to send and/or receive a variety of different kinds of information that are unrelated to testing. For example, an HSIO interface 116 may be used to transfer files to memory on the integrated circuit 102, to drive an external display, to charge a battery, to output audio, to receive audio, to communicate with a user interface device (e.g., a mouse, touchpad), etc.

It should be noted that the HSIO interface 116 may not be a dedicated test interface (e.g., a TAP). Although the high speed of an HSIO interface 116 may enable driving tests faster, there may be other advantages to using an HSIO interface 116. For example, even if the HSIO interface 116 is run at a lower speed than its full functional speed during test application, it may still be useful for some purposes such as debugging, etc.

In some configurations, the HSIO interface 116 may be an interface that is typically used in an integrated circuit design. For example, the HSIO interface 116 may be a USB interface for a computing device motherboard or a cellular phone board, etc.

The integrated circuit 102 may communicate with a test device 122. For example, the test device 122 may be coupled to the high-speed input/output (HSIO) interface 116. Examples of the test device 122 include an automated test equipment (ATE), digital multimeter, oscilloscope, computer, etc.

The high-speed input/output (HSIO) interface 116 may receive HSIO protocol test information 118 from the test device 122. The HSIO protocol test information 118 may include instructions and/or data for testing. Furthermore, the HSIO protocol test information 118 may be formatted according to HSIO protocols. For instance, if the high-speed input-output (HSIO) interface 116 is a USB interface, the HSIO protocol test information 118 may be formatted according to USB protocols (e.g., handshake protocol, token protocol, acknowledgement/negative acknowledgement (ACK/NACK) protocols, etc.).

The high-speed input/output (HSIO) interface 116 may send HSIO protocol test results 120 to the test device 122. For example, the high-speed input/output (HSIO) interface 116 may send data that is formatted according to HSIO protocols.

In one example, the high-speed input/output (HSIO) interface 116 may receive HSIO protocol test information 118 from the test device 122. The high-speed input/output (HSIO) interface 116 may generate controller protocol test information 112 based on the HSIO protocol test information 118. For example, the high-speed input/output (HSIO) interface 116 may remove the HSIO protocol formatting from the HSIO protocol test information 118, resulting in payload information. The high-speed input/output (HSIO) interface 116 may add controller protocol formatting to the payload information and/or format (e.g., convert, translate, etc.) the payload information into controller protocol test information 112, which is provided to the test controller 110. In other words, the high-speed input/output (HSIO) interface 116 may format the HSIO protocol test information into controller protocol test information 112.

The test controller 110 may control the test circuitry 104 based on the controller protocol test information 112. For example, the test controller 110 may send test information 106 to the test circuitry 104 based on the controller protocol test information 112. In another example, the test controller 110 may send other information (e.g., JTAG protocol test information) to another block/module (e.g., a dedicated test interface, a TAP, etc.) that controls the test circuitry 104. In some configurations, the test controller 110 may be separate from (e.g., not integrated into) the HSIO interface 116. For example, the test controller 110 may be a separate block or chip included on the integrated circuit 102.

In some configurations, the test controller 110 may control (e.g., orchestrate) one or more tests for the test circuitry 104. For example, the test controller 110 may receive an indicator from the test device 112 (through the HSIO interface 116) that specifies a particular block or element (e.g., test circuitry 104) of the integrated circuit 102 to be tested. The test controller 110 may then direct (e.g., route) testing data to the appropriate block or element to be tested. Some examples of these blocks or elements may include memory, scan chains, boundary scans, particular circuit elements, one or more registers, etc. In some configurations, for instance, the test controller 110 may translate the indicator into a particular address (or control information) that is used to direct test data or signals to a particular block or element. Additionally or alternatively, the test controller 110 may begin and/or end execution of a test. This may be based on one or more indicators received from the test device 122 (through the HSIO interface 116) or may be performed independently by the test controller 110.

The test circuitry 104 may perform one or more operations based on the test information 106. The test circuitry 104 may generate test results 108 based on the test information 106. The test results 108 may be provided to the test controller 110.

The test controller 110 may generate controller protocol test results 114 based on the test results 108. For example, the test controller 110 may format the test results 108 into controller protocol test results 114. For instance, the test controller 110 may add controller protocol information to the test results 108 and/or may structure the test results 108 according to a controller protocol. The test controller 110 may provide the controller protocol test results 114 to the high-speed input/output (HSIO) interface 116.

The high-speed input/output (HSIO) interface 116 may generate HSIO protocol test results 120 based on the controller protocol test results 114. For example, the high-speed input/output (HSIO) interface 116 may format the controller protocol test results 114 into HSIO protocol test results 120 for transmission to the test device 122. For instance, the high-speed input/output (HSIO) interface 116 may add HSIO protocol information to the HSIO protocol test results 120 and/or may remove controller protocol formatting from the controller protocol test results 114 and add HSIO protocol information and/or may structure the controller protocol test results 114 according to an HSIO protocol (e.g., USB protocols, MDDI protocols, etc.).

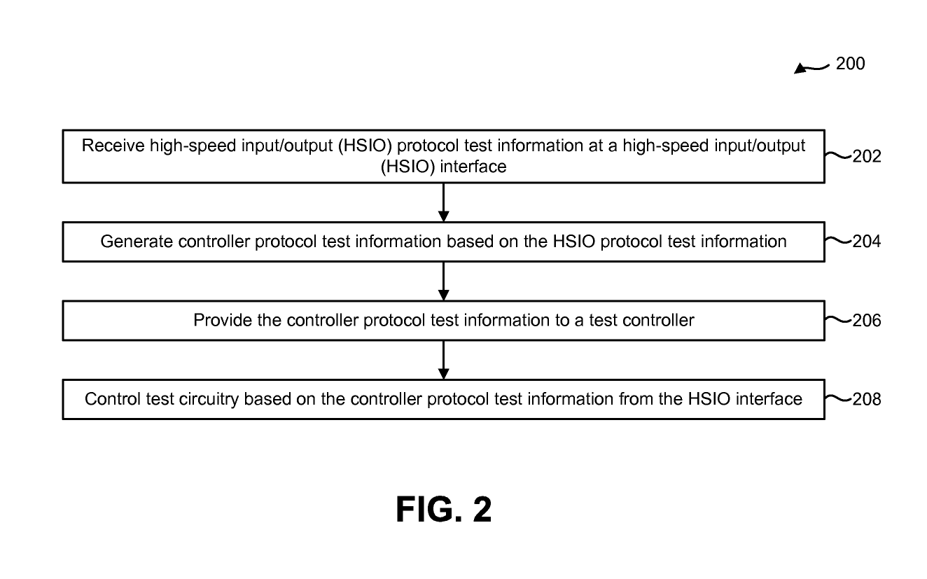

FIG. 2 is a flow diagram illustrating one configuration of a method 200 for testing using a high-speed input/output interface (HSIO). An integrated circuit 102 may receive 202 HSIO protocol test information 118 at a high-speed input/output (HSIO) interface 116. For example, the high-speed input/output (HSIO) interface 116 may receive HSIO protocol test information 118 that is formatted according to a high-speed input/output (HSIO) protocol (e.g., USB protocols, MDDI protocols, etc.). The HSIO protocol test information 118 may be received from a test device 122 (e.g., ATE).

The integrated circuit 102 (e.g., high-speed input/output (HSIO) interface 116) may generate 204 controller protocol test information 112 based on the HSIO protocol test information 118. For example, the high-speed input/output (HSIO) interface 116 may remove the HSIO protocol formatting from the HSIO protocol test information 118, resulting in payload information. The high-speed input/output (HSIO) interface 116 may add controller protocol formatting to the payload information and/or format (e.g., convert, translate, etc.) the payload information into controller protocol test information 112. The integrated circuit 102 (e.g., high-speed input/output (HSIO) interface 116) may provide 206 the controller protocol test information 112 to the test controller 110.

The integrated circuit 102 may control 208 test circuitry 104 based on the controller protocol test information 112. For example, the test controller 110 may send test information 106 to the test circuitry 104 based on the controller protocol test information 112 from the high-speed input/output (HSIO) interface 116. In another example, the test controller 110 may send other information (e.g., JTAG protocol test information) to another block/module (e.g., a TAP) that controls the test circuitry 104.

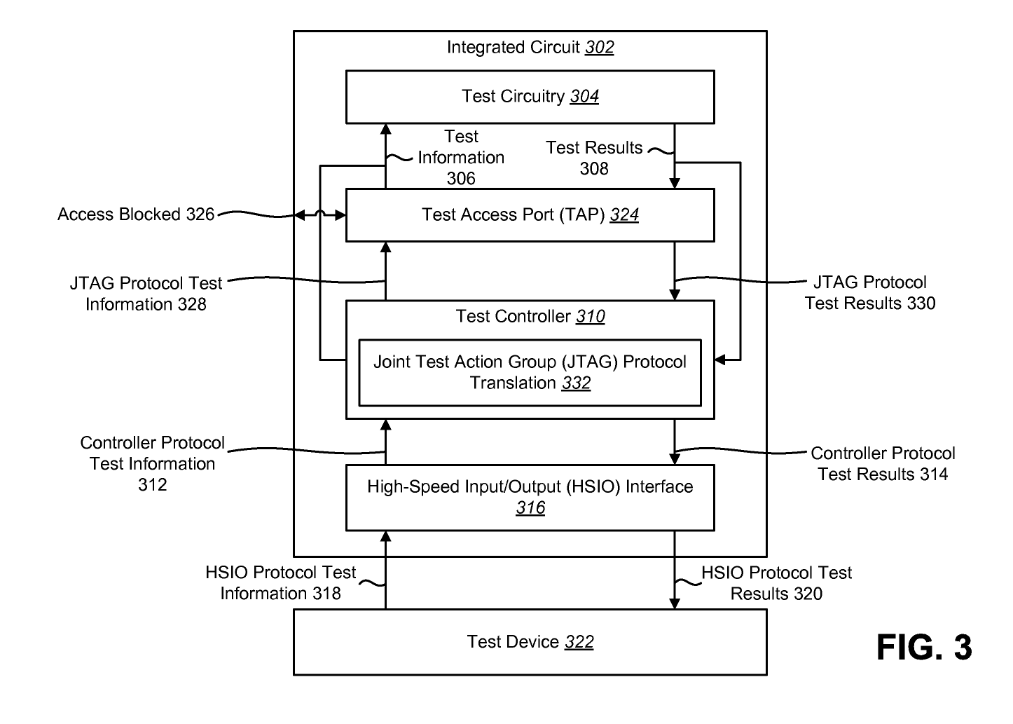

FIG. 3 is a block diagram illustrating a more specific configuration of an integrated circuit 302 for testing using a high-speed input/output (HSIO) interface 316. The integrated circuit 302 includes test circuitry 304, a test access port (TAP) 324, a test controller 310 and a high-speed input/output (HSIO) interface 316. The high-speed input/output (HSIO) interface 316 may be coupled to the test controller 310, the test controller 310 may be coupled to the test access port (TAP) 324 and the test access port (TAP) 324 may be coupled to the test circuitry 304. The test circuitry 304 may comprise one or more circuit elements for testing. For example, the test circuitry 304 may include one or more discrete components (e.g., resistors, capacitors, inductors), diodes, transistors, latches, registers (e.g., boundary scan registers), scan chains, flip-flops, memory cells, buses, digital logic elements, processors, application-specific integrated circuits (ASICs), etc. In some configurations, the integrated circuit 302 may be considered a device under test (DUT).

The test access port (TAP) 324 may be used to control the test circuitry 304 based on information provided by the test controller 310. For example, the test access port (TAP) 324 may provide test information 306 (e.g., instructions, data, etc.) to the test circuitry 304 in order to perform one or more tests on the test circuitry 304. The test access port (TAP) 324 may also receive test results 308 from the test circuitry 304. The test access port (TAP) 324 may be implemented in hardware, software or a combination of both. For example, the test access port (TAP) 324 may be implemented as an application-specific integrated circuit (ASIC), a microcontroller, a processor with instructions, etc. The test access port (TAP) 324 may be coupled to the test circuitry 304 and to the test controller 310. The test access port (TAP) 324 may be additional and/or alternative means for testing the test circuitry 304. This may be in addition to or alternatively from the test controller 310.

The test controller 310 may be used to control the test circuitry 304. The test controller 310 may include a joint test action group (JTAG) protocol translation block/module 332. The joint test action group (JTAG) protocol translation block/module 332 may allow the test controller 310 to format (e.g., translate) controller protocol test information 312 to JTAG protocol test information 328 and/or to format (e.g., translate) JTAG protocol test results 330 to controller protocol test results 314.

In one example, the test controller 310 may provide JTAG protocol test information 328 to the test access port (TAP) 324 in order to perform one or more tests on the test circuitry 304. The JTAG protocol test information 328 may include instructions and/or data that may be used to perform one or more tests on the test circuitry 304 via the test access port (TAP) 324. The JTAG protocol test information 328 may be formatted according to JTAG protocols.

The test controller 310 may also receive JTAG protocol test results 330 from the test access port (TAP) 324. The test controller 310 may be implemented in hardware, software or a combination of both. For example, the test controller 310 may be implemented as an application-specific integrated circuit (ASIC), a microcontroller, a processor with instructions, etc. The test controller 310 may be coupled to the test access port (TAP) 324 and to the high-speed input/output (HSIO) interface 316.

In some configurations, the test controller 310 may send test information 306 and/or receive test results 308 independently from the test access port (TAP) 324 in addition to or alternatively from JTAG protocol test information 328 provided to the test access port (TAP) 324 and/or from JTAG protocol test results 330 received from the test access port (TAP) 324. For example, the test circuitry 304 may include multiple blocks/modules (e.g., different parts) for testing. In this case, the test controller 310 may test one or more blocks/modules of the test circuitry 304 through the test access port (TAP) 324 and/or may independently test one or more other blocks/modules (e.g., memory, scan chains, etc.) of the test circuitry 304.

In some configurations, external access to the test access port (TAP) 324 may be blocked 326. For example, external access to the test access port (TAP) 324 may be provided for in early stages of manufacturing, but may be blocked after a certain stage. In some configurations, the systems and methods disclosed herein may provide access to the test access port (TAP) 324 for testing the test circuitry 304 even after (direct) external access to the test access port (TAP) 324 is blocked 326.

The high-speed input/output (HSIO) interface 316 may be used to receive information from another device and/or may be used to send (e.g., output) information to another device. The high-speed input/output (HSIO) interface 316 may include one or more physical ports, protocols and/or logic used to support the interface. Examples of the high-speed input/output (HSIO) interface 316 include universal serial bus (USB) interfaces, mobile display digital interfaces (MDDIs), etc.

The high-speed input/output (HSIO) interface 316 may send controller protocol test information 312 to the test controller 310. The controller protocol test information 312 may include instructions and/or data that may be used for testing the test circuitry 304. The controller protocol test information 312 (and/or controller protocol test results 314) may conform to a controller protocol. In other words, the controller protocol test information 312 may be formatted according to a protocol used by the test controller 310. For instance, the controller protocol test information 312 may be structured according to particular message, frame, packet and/or timing structures as specified by the controller protocol.

The high-speed input/output (HSIO) interface 316 may receive controller protocol test results 314. The controller protocol test results 314 may include information (e.g., data) generated based on testing the test circuitry 304. The controller protocol test results 314 may be formatted according to the controller protocol. In other words, the controller protocol test results 314 may be formatted according to a protocol used by the test controller 310. For instance, the controller protocol test results 314 may be structured according to particular message, frame, packet and/or timing structures as specified by the controller protocol. Several examples of controller protocols are given in greater detail below. The high-speed input/output (HSIO) interface 316 may format the controller protocol test results 314 into HSIO protocol test results 320.

The high-speed input/output (HSIO) interface 316 may receive HSIO protocol test information 318 from a test device 322 and/or may send HSIO protocol test results 320 to the test device 322. However, it should be noted that the HSIO interface 316 may be used to send and/or receive a variety of different kinds of information that are unrelated to testing. For example, an HSIO interface 316 may be used to transfer files to memory on the integrated circuit 302, to drive an external display, to communicate with a user interface device (e.g., a mouse, touchpad), etc.

In some configurations, the HSIO interface 316 may be an interface that is typically used in an integrated circuit design. For example, the HSIO interface 316 may be a USB interface for a computing device motherboard or a cellular phone board, etc.

The integrated circuit 302 may communicate with a test device 322. For example, the test device 322 may be coupled to the high-speed input/output (HSIO) interface 316. Examples of the test device 322 include an automated test equipment (ATE), digital multimeter, oscilloscope, computer, etc.

The high-speed input/output (HSIO) interface 316 may receive HSIO protocol test information 318 from the test device 322. The HSIO protocol test information 318 may include instructions and/or data for testing. Furthermore, the HSIO protocol test information 318 may be formatted according to HSIO protocols. For instance, if the high-speed input-output (HSIO) interface 316 is a USB interface, the HSIO protocol test information 318 may be formatted according to USB protocols (e.g., handshake protocol, token protocol, acknowledgement/negative acknowledgement (ACK/NACK) protocols, etc.).

The high-speed input/output (HSIO) interface 316 may send HSIO protocol test results 320 to the test device 322. For example, the high-speed input/output (HSIO) interface 316 may send data that is formatted according to HSIO protocols.

In one example, the high-speed input/output (HSIO) interface 316 may receive HSIO protocol test information 318 from the test device 322. The high-speed input/output (HSIO) interface 316 may generate controller protocol test information 312 based on the HSIO protocol test information 318. For example, the high-speed input/output (HSIO) interface 316 may remove the HSIO protocol formatting from the HSIO protocol test information 318, resulting in payload information. The high-speed input/output (HSIO) interface 316 may add controller protocol formatting to the payload information and/or format (e.g., convert, translate, etc.) the payload information into controller protocol test information 312, which is provided to the test controller 310. In other words, the high-speed input/output (HSIO) interface 316 may format the HSIO protocol test information 318 into the controller protocol test information 312 that is provided to the test controller 310.

The test controller 310 may control the test circuitry 304 based on the controller protocol test information 312. For example, the test controller 310 may format (e.g., translate) the controller protocol test information 312 into JTAG protocol test information 328, which is provided to the test access port (TAP) 324 to control the test circuitry 304.

The test access port (TAP) 324 may control the test circuitry 304 based on the JTAG protocol test information 328. For example, the test access port (TAP) 324 may send test information 306 to the test circuitry 304 based on the JTAG protocol test information 328.

The test circuitry 304 may perform one or more operations based on the test information 306. The test circuitry 304 may generate test results 308 based on the test information 306. The test results 308 may be provided to the test access port (TAP) 324.

The test access port (TAP) 324 may generate JTAG protocol test results 330 based on the test results 308 provided by the test circuitry 304. For example, the JTAG protocol test results 330 may include the test results 308 that are formatted to conform to JTAG protocol(s). The JTAG protocol test results 330 may be provided to the test controller 310.

The test controller 310 may generate controller protocol test results 314 based on the JTAG protocol test results 330. For example, the test controller 310 may format the JTAG protocol test results 330 into controller protocol test results 314. For instance, the test controller 310 may remove JTAG protocol formatting from the JTAG protocol test results 330 and add controller protocol information according to a controller protocol. The test controller 310 may provide the controller protocol test results 314 to the high-speed input/output (HSIO) interface 316.

The high-speed input/output (HSIO) interface 316 may generate HSIO protocol test results 320 based on the controller protocol test results 314. For example, the high-speed input/output (HSIO) interface 316 may format the controller protocol test results 314 into HSIO protocol test results 320 for transmission to the test device 322. For instance, the high-speed input/output (HSIO) interface 316 may remove controller protocol formatting from the controller protocol test results 314, add HSIO protocol information and/or may structure the controller protocol test results 314 according to an HSIO protocol (e.g., USB protocols, MDDI protocols, etc.).

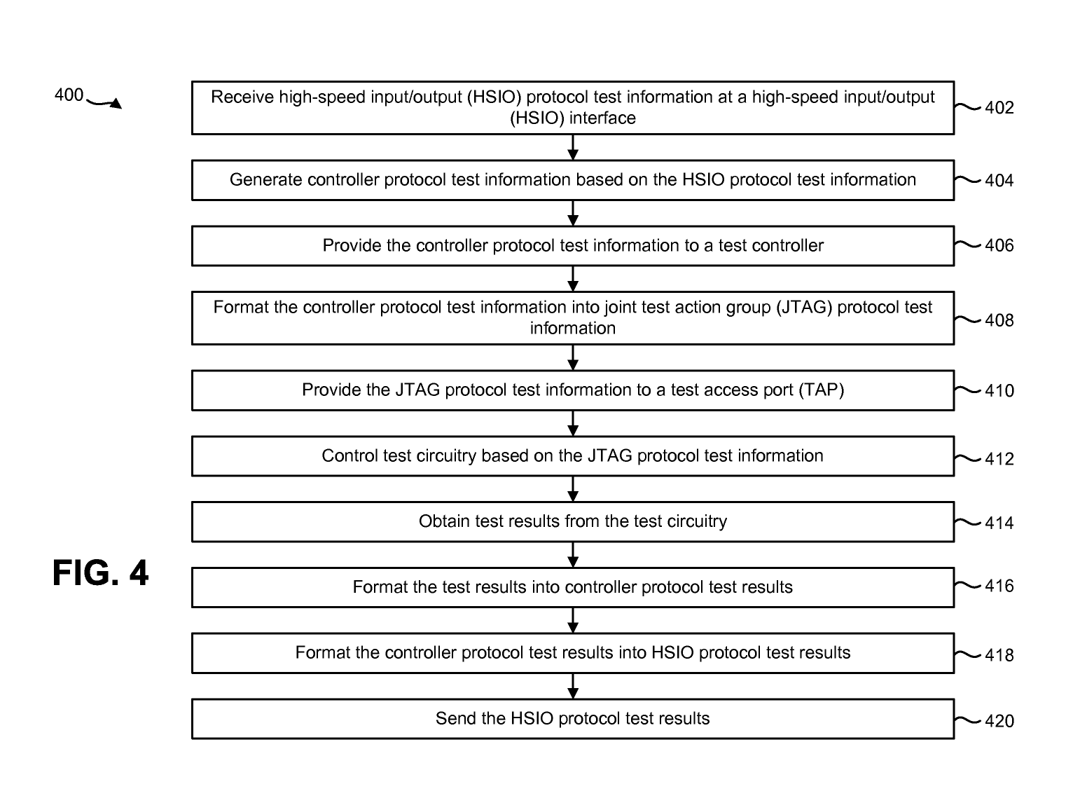

FIG. 4 is a flow diagram illustrating a more specific configuration of a method 400 for testing using a high-speed input/output interface (HSIO). An integrated circuit 302 may receive 402 high-speed input/output (HSIO) protocol test information 318 at a high-speed input/output (HSIO) interface 316. For example, the high-speed input/output (HSIO) interface 316 may receive HSIO protocol test information 318 that is formatted according to a high-speed input/output (HSIO) protocol (e.g., USB protocols, MDDI protocols, etc.). The HSIO protocol test information 318 may be received from a test device 322 (e.g., ATE).

The integrated circuit 302 (e.g., high-speed input/output (HSIO) interface 316) may generate 404 controller protocol test information 312 based on the HSIO protocol test information 318. For example, the high-speed input/output (HSIO) interface 316 may remove the HSIO protocol formatting from the HSIO protocol test information 318, resulting in payload information. The high-speed input/output (HSIO) interface 316 may add controller protocol formatting to the payload information and/or format (e.g., convert, translate, etc.) the payload information into controller protocol test information 312. The integrated circuit 302 (e.g., high-speed input/output (HSIO) interface 316) may provide 406 the controller protocol test information 312 to the test controller 310.

The integrated circuit 302 (e.g., test controller 310) may format 408 the controller protocol test information 312 into joint test action group (JTAG) protocol test information 328. For example, the test controller 310 may translate the controller protocol test information 312 into JTAG protocol test information 328 by removing controller protocol formatting from the controller protocol test information 312 and adding JTAG protocol formatting. The integrated circuit 102 (e.g., test controller 310) may provide 410 the JTAG protocol test information 328 to the test access port (TAP) 324.

The integrated circuit 302 may control 412 test circuitry 304 based on the JTAG protocol test information 328. For example, the test access port (TAP) 324 may send test information 306 to the test circuitry 304 based on the JTAG protocol test information 328.

The integrated circuit 302 may obtain 414 test results 308 from the test circuitry 304. For example, the test circuitry 304 may generate test results 308 when provided with test information 306. In some configurations, the integrated circuit 302 (e.g., test controller 310 and/or test access port (TAP) 324) may provide a command (e.g., a test data out (TDO) instruction) to output test results 308. In some configurations, the test results 308 may be obtained 414 via a test access port (TAP) 324. In this case, the test results 308 may be formatted as JTAG protocol test results 330. However, in other configurations, the test results 308 may be obtained 414 independently from the test access port (TAP) 324.

The integrated circuit 302 may format 416 the test results 308 (and/or JTAG protocol test results 330, for example) into controller protocol test results 314. For example, the test controller 310 may format 416 (e.g., convert, translate, etc.) the test results 308 (or the JTAG protocol test results 330, for example) into controller protocol test results 314. In one configuration, the integrated circuit 302 (e.g., test controller 310) may add controller protocol formatting to the test results 308. In another configuration, the integrated circuit 302 (e.g., test controller 310) may remove JTAG protocol formatting from JTAG protocol test results 330 and add controller protocol formatting.

The integrated circuit 302 may format 418 the controller protocol test results 314 into HSIO protocol test results 320. For example, the test controller 310 may provide the controller protocol test results 314 to the high-speed input/output (HSIO) interface 316. The high-speed input/output (HSIO) interface 316 may then format 418 the controller protocol test results 314 into HSIO protocol test results 320 by removing controller protocol formatting from the controller protocol test results 314 and adding HSIO protocol formatting. The integrated circuit 302 may send 420 the HSIO protocol test results 320. For example, the high-speed input/output (HSIO) interface 316 may output or provide the HSIO protocol test results 320 to an external test device 322.

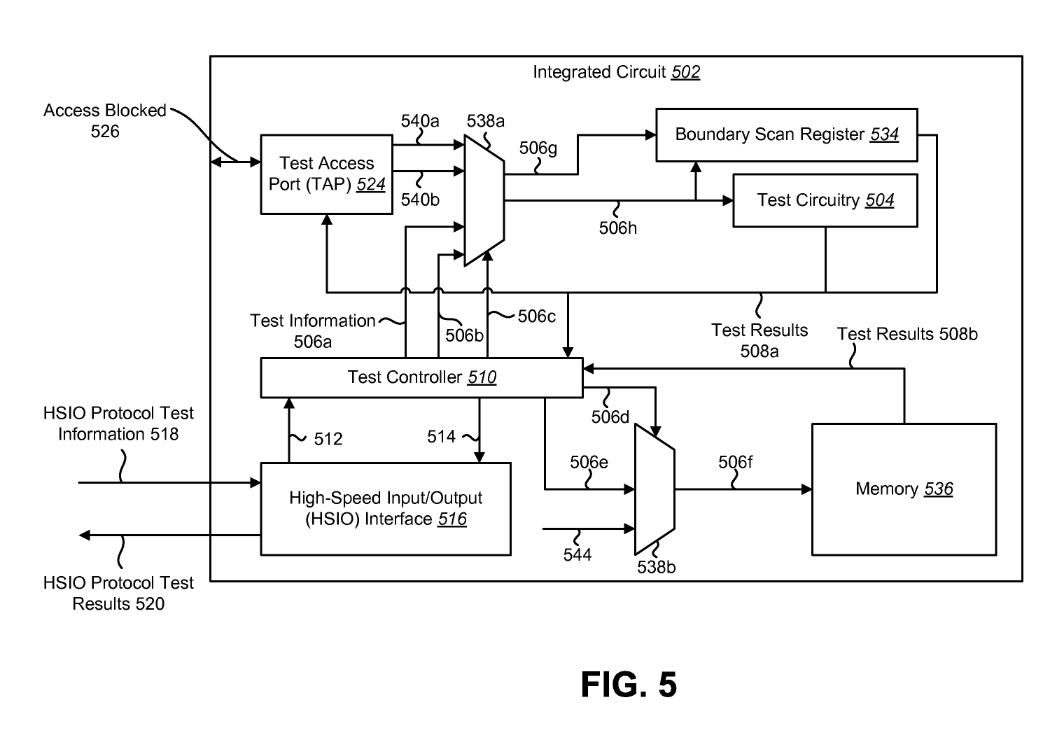

FIG. 5 is a block diagram illustrating one example of an integrated circuit 502 in which testing using a high-speed input/output interface (HSIO) 516 may be implemented. In particular, the test controller 510 (which may be implemented in hardware and/or software) communicates with (e.g., sends information to and/or receives information from) an external device (e.g., a test device) through a high-speed input/output (HSIO) interface 516. In this example, the test controller 510 intercepts one or more signals 540a-b (e.g., test control and data signals) provided by (e.g., after) a test access port (TAP) 524 and provides test information 506a-c (e.g., control and data values) based on controller protocol test information 512 (e.g., instructions) it 510 obtains from the high-speed input/output (HSIO) interface 516. Thus, one or more signals 540a-b (e.g., test control and/or test data signals) may be intercepted after the TAP 524. The test controller 510 may also deliver controller protocol test results 514 (e.g., responses) to the external device through the high-speed input/output (HSIO) interface 516.

In the example illustrated in FIG. 5, other tests that may not be possible through a TAP 524 interface (which may be relatively slow compared to an HSIO interface 516) may be additionally supported. For example, test information 506e (e.g., a high-speed test data stream) may be routed to memory 536 on the integrated circuit 502 from the high-speed input/output (HSIO) interface 516.

More detail regarding the example illustrated in FIG. 5 is given hereafter. The integrated circuit 502 includes test circuitry 504, a test access port (TAP) 524, a test controller 510, a high-speed input/output (HSIO) interface 516, multiplexer A 538a, multiplexer B 538b, one or more boundary scan registers 534 and memory 536. The test circuitry 504 may comprise one or more circuit elements for testing. In some configurations, the boundary scan register 534 may be considered part of the test circuitry 504. Additionally or alternatively, the memory 536 may be considered part of the test circuitry 504 in some configurations (although the memory 536 may not be accessed by or through the test access port (TAP) 524, for example). The test circuitry 504 may include one or more discrete components (e.g., resistors, capacitors, inductors), diodes, transistors, latches, registers (e.g., boundary scan registers), scan chains, flip-flops, memory cells, buses, digital logic, processors, application-specific integrated circuits (ASICs), etc. In some configurations, the integrated circuit 502 may be considered a device under test (DUT).

The test access port (TAP) 524 (e.g., TAP 524 interface) may be a dedicated test interface that is typically used to control the test circuitry 504 and/or boundary scan register 534. For example, the test access port (TAP) 524 may provide information 540a-b to the test circuitry 504 and/or boundary scan register 534 in order to perform one or more tests. For instance, the test access port (TAP) 524 may provide information 540a-b to multiplexer A 538a that may be selected as test information 506g-h that is provided to the boundary scan register 534 and/or the test circuitry 504. The test access port (TAP) 524 may also receive test results 508a from the test circuitry 504 and/or boundary scan register 534.

The test access port (TAP) 524 may be implemented in hardware, software or a combination of both. For example, the test access port (TAP) 524 may be implemented as an application-specific integrated circuit (ASIC), a microcontroller, a processor with instructions, etc. The test access port (TAP) 524 may be coupled to the test circuitry 504 (or certain parts of test circuitry 504). In some configurations, the test access port (TAP) 524 may only be externally accessed in certain stages of manufacturing. However, external access to the test access port (TAP) 524 may eventually be blocked 526.

The high-speed input/output (HSIO) interface 516 may receive HSIO protocol test information 518 from an external device (e.g., test device). The HSIO protocol test information 518 may include instructions and/or data for testing. Furthermore, the HSIO protocol test information 518 may be formatted according to HSIO protocols.

The high-speed input/output (HSIO) interface 516 may generate controller protocol test information 512 based on the HSIO protocol test information 518, which is provided to the test controller 510. The test controller 510 may control the test circuitry 504 based on the controller protocol test information 512. For example, the test controller 510 may generate test information 506a-e based on the controller protocol test information 512.

The test controller 510 may be used to control the test circuitry 504 (including the boundary scan register 534 and/or memory 536, for example). In the example illustrated in FIG. 5, the test controller 510 is coupled to multiplexer A 538a and multiplexer B 538b. The test controller 510 provides test information 506a-e in order to perform one or more tests. For instance, the test controller 510 may provide test information 506a-b to multiplexer A 538a. Additionally, the test controller 510 may use test information 506c to control multiplexer A 538a. For example, the test controller 510 may use some test information 506c (e.g., an instruction, control signal, etc.) to select test information 506a-b as test information 506g-h (instead of information 540a-b from the TAP 524). For example, the test controller 510 may “intercept” information 540a-b (if any) from the TAP 524 interface and provide test information 506a-b (that is based on HSIO protocol test information 518 received by the high-speed input/output (HSIO) interface 516) as test information 506g-h instead of information 540a-b from the TAP 524 interface.

The boundary scan register 534 and/or test circuitry 504 may perform one or more operations based on the test information 506g-h. For example, the boundary scan register 534 may apply certain bits to particular pins of the integrated circuit 502 and/or the test circuitry 504 may apply the test information 506h. The boundary scan register 534 and/or the test circuitry 504 may generate test results 508a based on the test information 506g-h. The test results 508a may be provided to the test controller 510 (and/or to the test access port (TAP) 524).

Additionally or alternatively, the test controller 510 may perform other tests that may not be possible through a TAP 524 interface. For example, the test controller 510 may use some test information 506d (e.g., an instruction, control signal, etc.) to control multiplexer B 538b in order to route test information 506e (e.g., a high-speed test data stream) to memory 536 on the integrated circuit 502 from the high-speed input/output (HSIO) interface 516. This test information 506e from the test controller 510 may be selected as test information 506f provided to memory 536 from multiplexer B 538b in addition to or alternatively from other data 544.

It should be noted that the test controller 510 may format the control protocol test information 512 into test information 506a-e. In some configurations, some test information 506a-c may be provided in a different format from other test information 506d-e.

In some configurations, the high-speed input/output (HSIO) interface 516 may access the memory 536 in order to obtain results from providing the test information 506e to the memory 536 as data 506f. For example, the high-speed input/output (HSIO) interface 516 may directly access the memory 536 or may obtain test results 508b from the memory 536 via the test controller 510 (formatted as controller protocol test results 514, for example).

The test controller 510 may generate controller protocol test results 514 based on the test results 508a. For example, the test controller 510 may format the test results 508a into controller protocol test results 514. For instance, the test controller 510 may add controller protocol information according to a controller protocol. The test controller 510 may provide the controller protocol test results 514 to the high-speed input/output (HSIO) interface 516.

The high-speed input/output (HSIO) interface 516 may generate HSIO protocol test results 520 based on the controller protocol test results 514. For example, the high-speed input/output (HSIO) interface 516 may format the controller protocol test results 514 into HSIO protocol test results 520 for transmission to a test device. For instance, the high-speed input/output (HSIO) interface 516 may remove controller protocol formatting from the controller protocol test results 514 and add HSIO protocol information and/or may structure the controller protocol test results 514 according to an HSIO protocol (e.g., USB protocols, MDDI protocols, etc.).

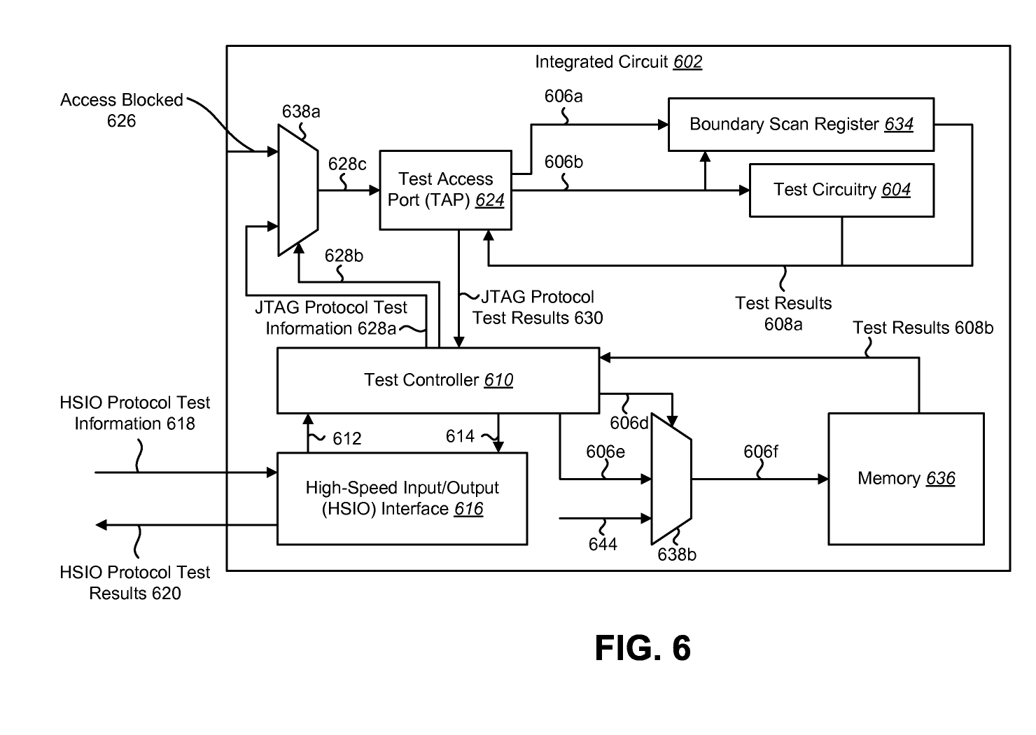

FIG. 6 is a block diagram illustrating another example of an integrated circuit 602 in which testing using a high-speed input/output interface (HSIO) 616 may be implemented. In this example, the test access port (TAP) 624 interface signals may be intercepted before the TAP 624. In other examples, test control and/or test data signals may be intercepted at any point in downstream logic.

More detail regarding the example illustrated in FIG. 6 is given hereafter. The integrated circuit 602 includes test circuitry 604, a test access port (TAP) 624, a test controller 610, a high-speed input/output (HSIO) interface 616, multiplexer A 638a, multiplexer B 638b, one or more boundary scan registers 634 and memory 636. The test circuitry 604 may comprise one or more circuit elements for testing. In some configurations, the boundary scan register 634 may be considered part of the test circuitry 604. Additionally or alternatively, the memory 636 may be considered part of the test circuitry 604 in some configurations (although the memory 636 may not be accessed by or through the test access port (TAP) 624, for example).

The test access port (TAP) 624 (e.g., TAP 624 interface) may typically be used to control the test circuitry 604 and/or boundary scan register 634. For example, the test access port (TAP) 624 may provide test information 606a-b to the test circuitry 604 and/or boundary scan register 634 in order to perform one or more tests. For instance, the test access port (TAP) 624 may provide test information 606a-b based on an external signal through multiplexer A 638a. However, access may become blocked 626 to the external signal. The test access port (TAP) 624 may receive test results 608a from the test circuitry 604 and/or boundary scan register 634. The test access port (TAP) 624 may be coupled to the test circuitry 604.

The high-speed input/output (HSIO) interface 616 may receive HSIO protocol test information 618 from an external device (e.g., test device). The HSIO protocol test information 618 may include instructions and/or data for testing. Furthermore, the HSIO protocol test information 618 may be formatted according to HSIO protocols.

The high-speed input/output (HSIO) interface 616 may generate controller protocol test information 612 based on the HSIO protocol test information 618, which is provided to the test controller 610. The test controller 610 may control the test circuitry 604 based on the controller protocol test information 612. For example, the test controller 610 may generate JTAG protocol test information 628a-b based on the controller protocol test information 612.

The test controller 610 may be used to control the test circuitry 604 (including the boundary scan register 634 and/or memory 636, for example). In the example illustrated in FIG. 6, the test controller 610 is coupled to multiplexer A 638a. The test controller 610 provides JTAG protocol test information 628a-b (and/or test information 606d-e) in order to perform one or more tests. For instance, the test controller 610 may provide JTAG protocol test information 628a to multiplexer A 638a. Additionally, the test controller 610 may use JTAG protocol test information 628b to control multiplexer A 638a. For example, the test controller 610 may use some JTAG protocol test information 628b (e.g., an instruction, control signal, etc.) to select JTAG protocol test information 628a (instead of information, if any, from an external route that may have its access blocked 626) as selected JTAG protocol test information 628c that is provided to the test access port (TAP) 624. The selected JTAG protocol test information 628c may in turn be used to generate test information 606a-b. For example, the test controller 610 may “intercept” external information (if any) en-route to the TAP 624 interface and provide JTAG protocol test information 628a (that is based on HSIO protocol test information 618 received by the high-speed input/output (HSIO) interface 616) to generate test information 606a-b instead of external information (if any) en-route to the test access port (TAP) 624.

The boundary scan register 634 and/or test circuitry 604 may perform one or more operations based on the test information 606a-b. For example, the boundary scan register 634 may apply certain bits to particular pins of the integrated circuit 602 and/or the test circuitry 604 may apply the test information 606b. The boundary scan register 634 and/or the test circuitry 604 may generate test results 608a based on the test information 606a-b. The test results 608a may be provided to the test access port (TAP) 624.

Additionally or alternatively, the test controller 610 may perform other tests that may not be possible through a TAP 624 interface. For example, the test controller 610 may use some test information 606d (e.g., an instruction, control signal, etc.) to control multiplexer B 638b in order to route test information 606e (e.g., a high-speed test data stream) to memory 636 on the integrated circuit 602 from the high-speed input/output (HSIO) interface 616. This test information 606e from the test controller 610 may be selected as test information 606f provided to memory 636 from multiplexer B 638b in addition to or alternatively from other data 644.

In some configurations, the high-speed input/output (HSIO) interface 616 may access the memory 636 in order to obtain results from providing the test information 606e to the memory 636 as data 606f. For example, the high-speed input/output (HSIO) interface 616 may directly access the memory 636 or may obtain test results 608b from the memory 636 via the test controller 610 (formatted as controller protocol test results 614, for example).

The test controller 610 may receive JTAG protocol test results 630 from the test access port (TAP) 624. For example, the test access port (TAP) 624 may provide JTAG protocol test results 630 to the test controller 610 based on the test results 608a received from the boundary scan register 634 and/or test circuitry 604.

The test controller 610 may generate controller protocol test results 614 based on the JTAG protocol test results 630. For example, the test controller 610 may format the JTAG protocol test results 630 into controller protocol test results 614. For instance, the test controller 610 may remove JTAG protocol formatting from the JTAG protocol test results 630 and add controller protocol information (e.g., structure) according to a controller protocol. The test controller 610 may provide the controller protocol test results 614 to the high-speed input/output (HSIO) interface 616.

The high-speed input/output (HSIO) interface 616 may generate HSIO protocol test results 620 based on the controller protocol test results 614. For example, the high-speed input/output (HSIO) interface 616 may format the controller protocol test results 614 into HSIO protocol test results 620 for transmission to a test device. For instance, the high-speed input/output (HSIO) interface 616 may remove controller protocol formatting from the controller protocol test results 614 and add HSIO protocol information and/or may structure the controller protocol test results 614 according to an HSIO protocol (e.g., USB protocols, MDDI protocols, etc.).

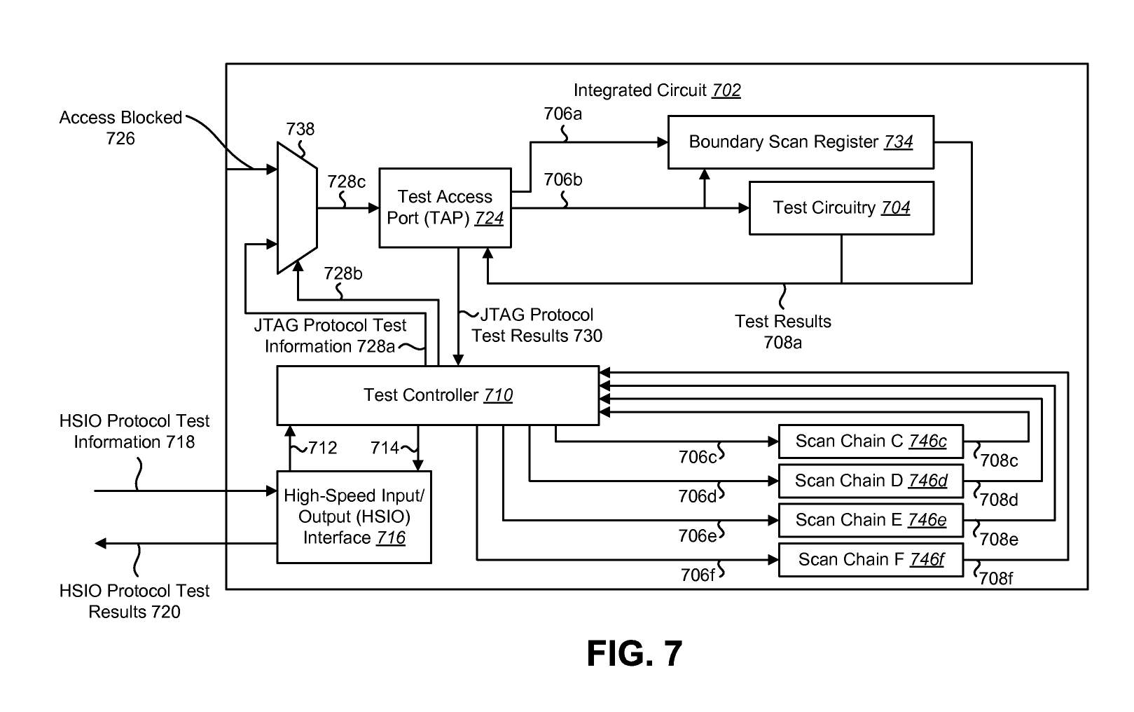

FIG. 7 is a block diagram illustrating another example of an integrated circuit 702 in which testing using a high-speed input/output interface (HSIO) 716 may be implemented. In this example, the systems and methods disclosed herein may be used to drive multiple scan channels. For instance, a high-speed input/output (HSIO) interface 716 physical (PHY) layer may send controller protocol test information 712 to the test controller 710 in a parallel format, which may be used to drive multiple scan chains 746c-f. Furthermore, the high-speed input/output (HSIO) interface 716 may receive controller protocol test results 714 from the test controller 710 in a parallel format.

More detail regarding the example illustrated in FIG. 7 is given hereafter. The integrated circuit 702 includes test circuitry 704, a test access port (TAP) 724, a test controller 710, a high-speed input/output (HSIO) interface 716, a multiplexer 738, one or more boundary scan registers 734, and one or more scan chains 746. The test circuitry 704 may comprise one or more circuit elements for testing. In some configurations, the boundary scan register 734 may be considered part of the test circuitry 704. Additionally or alternatively, the one or more scan chains 746 may be considered part of the test circuitry 704 (although the scan chain(s) 746 may not be accessed by or through the test access port (TAP) 724).

The test access port (TAP) 724 (e.g., TAP 724 interface) may typically be used to control the test circuitry 704 and/or boundary scan register 734. For example, the test access port (TAP) 724 may provide test information 706a-b to the test circuitry 704 and/or boundary scan register 734 in order to perform one or more tests. For instance, the test access port (TAP) 724 may provide test information 706a-b based on an external signal from the multiplexer 738. However, access may become blocked 726 to the external signal. The test access port (TAP) 724 may receive test results 708a from the test circuitry 704 and/or boundary scan register 734. The test access port (TAP) 724 may be coupled to the test circuitry 704.

The high-speed input/output (HSIO) interface 716 may receive HSIO protocol test information 718 from an external device (e.g., test device). The HSIO protocol test information 718 may include instructions and/or data for testing. Furthermore, the HSIO protocol test information 718 may be formatted according to HSIO protocols. In some configurations, the high-speed input/output (HSIO) interface 716 may receive the HSIO protocol test information 718 in a parallel format. In other configurations, the high-speed input/output (HSIO) interface 716 may receive the HSIO protocol test information 718 in a serial format.

The high-speed input/output (HSIO) interface 716 may generate controller protocol test information 712 based on the HSIO protocol test information 718. The controller protocol test information 712 may be provided to the test controller 710 in a parallel format in some configurations. In other configurations, the controller protocol test information 712 may be provided to the test controller 710 in a serial format. The test controller 710 may control the test circuitry 704 based on the controller protocol test information 712. For example, the test controller 710 may generate JTAG protocol test information 728a-b based on the controller protocol test information 712.

The test controller 710 may be used to control the test circuitry 704 (including the boundary scan register 734 and/or scan chain(s) 746, for example). In the example illustrated in FIG. 7, the test controller 710 is coupled to the multiplexer 738. The test controller 710 provides JTAG protocol test information 728a-b (and/or test information 706c-f) in order to perform one or more tests. For instance, the test controller 710 may provide JTAG protocol test information 728a to the multiplexer 738. Additionally, the test controller 710 may use JTAG protocol test information 728b to control the multiplexer 738. For example, the test controller 710 may use some JTAG protocol test information 728b (e.g., an instruction, control signal, etc.) to select JTAG protocol test information 728a (instead of information, if any, from an external route that may have its access blocked 726) as selected JTAG protocol test information 728c that is provided to the test access port (TAP) 724. The selected JTAG protocol test information 728c may in turn be used to generate test information 706a-b. For example, the test controller 710 may “intercept” external information (if any) en-route to the TAP 724 interface and provide JTAG protocol test information 728a (that is based on HSIO protocol test information 718 received by the high-speed input/output (HSIO) interface 716) to generate test information 706a-b instead of external information (if any) en-route to the test access port (TAP) 724.

The boundary scan register 734 and/or test circuitry 704 may perform one or more operations based on the test information 706a-b. For example, the boundary scan register 734 may apply certain bits to particular pins of the integrated circuit 702 and/or the test circuitry 704 may apply the test information 706b. The boundary scan register 734 and/or the test circuitry 704 may generate test results 708a based on the test information 706a-b. The test results 708a may be provided to the test access port (TAP) 724.

Additionally or alternatively, the test controller 710 may perform other tests. For example, the test controller 710 may use some parallel test information 706c-f to test scan chains 746c-f (based on HSIO protocol test information 718 received by the high-speed input/output (HSIO) interface 716). In one configuration, each of the scan chains 746c-f may include one or more flip-flops that can be tested by providing test information 706c-f. The scan chains 746c-f may produce test results 708c-f that may be provided to the test controller 710.

The test controller 710 may receive JTAG protocol test results 730 from the test access port (TAP) 724. For example, the test access port (TAP) 724 may provide JTAG protocol test results 730 to the test controller 710 based on the test results 708a received from the boundary scan register 734 and/or test circuitry 704.

The test controller 710 may generate controller protocol test results 714 based on the JTAG protocol test results 730 and/or the test results 708c-f. For example, the test controller 710 may format the JTAG protocol test results 730 and/or the test results 708c-f into controller protocol test results 714. For instance, the test controller 710 may remove JTAG protocol formatting from the JTAG protocol test results and add controller protocol information (e.g., structure) according to a controller protocol. Additionally or alternatively, the test controller 710 may add controller protocol information (e.g., structure) to the test results 708c-f according to a controller protocol. The test controller 710 may provide the controller protocol test results 714 to the high-speed input/output (HSIO) interface 716.

The high-speed input/output (HSIO) interface 716 may generate HSIO protocol test results 720 based on the controller protocol test results 714. For example, the high-speed input/output (HSIO) interface 716 may format the controller protocol test results 714 into HSIO protocol test results 720 for transmission to a test device. For instance, the high-speed input/output (HSIO) interface 716 may remove controller protocol formatting from the controller protocol test results 714 and add HSIO protocol information and/or may structure the controller protocol test results 714 according to an HSIO protocol (e.g., USB protocols, MDDI protocols, etc.).

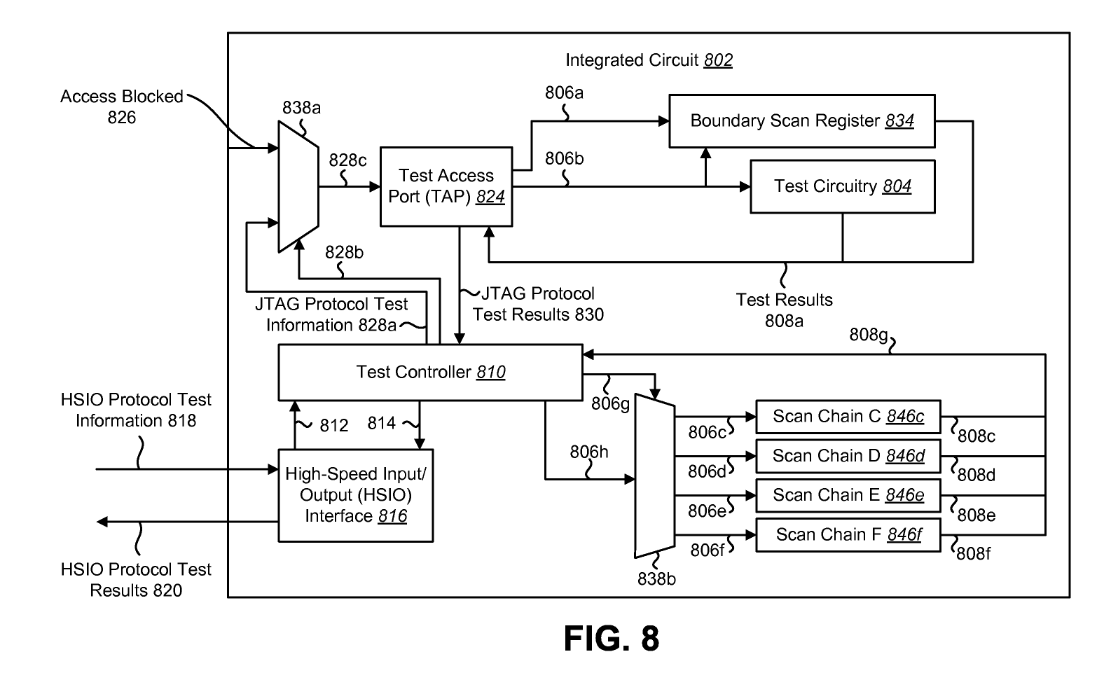

FIG. 8 is a block diagram illustrating another example of an integrated circuit 802 in which testing using a high-speed input/output interface (HSIO) 816 may be implemented. In this example, controller protocol test information 812 may be received by the test controller 810 as a high-speed serial stream. Serial test information 806h may be decoded (e.g., demultiplexed) into multiple scan channels. For instance, an 80 megabits per second (Mbps) data stream (e.g., test information 806h) may be used to drive four scan chains 846c-f at 20 Mbps each.

More detail regarding the example illustrated in FIG. 8 is given hereafter. The integrated circuit 802 includes test circuitry 804, a test access port (TAP) 824, a test controller 810, a high-speed input/output (HSIO) interface 816, multiplexer A 838a, multiplexer B 838b, one or more boundary scan registers 834, and one or more scan chains 846. The test circuitry 804 may comprise one or more circuit elements for testing. In some configurations, the boundary scan register 834 may be considered part of the test circuitry 804. Additionally or alternatively, the one or more scan chains 846 may be considered part of the test circuitry 804 (although the scan chain(s) 846 may not be accessed by or through the test access port (TAP) 824).

The test access port (TAP) 824 (e.g., TAP 824 interface) may typically be used to control the test circuitry 804 and/or boundary scan register 834. For example, the test access port (TAP) 824 may provide test information 806a-b to the test circuitry 804 and/or boundary scan register 834 in order to perform one or more tests. For instance, the test access port (TAP) 824 may provide test information 806a-b based on an external signal from multiplexer A 838a. However, access may become blocked 826 to the external signal. The test access port (TAP) 824 may receive test results 808a from the test circuitry 804 and/or boundary scan register 834. The test access port (TAP) 824 may be coupled to the test circuitry 804.

The high-speed input/output (HSIO) interface 816 may receive HSIO protocol test information 818 from an external device (e.g., test device). The HSIO protocol test information 818 may include instructions and/or data for testing. Furthermore, the HSIO protocol test information 818 may be formatted according to HSIO protocols. In some configurations, the high-speed input/output (HSIO) interface 816 may receive the HSIO protocol test information 818 in a serial format.

The high-speed input/output (HSIO) interface 816 may generate controller protocol test information 812 based on the HSIO protocol test information 818. The controller protocol test information 812 may be provided to the test controller 810 in a serial format in some configurations. The test controller 810 may control the test circuitry 804 based on the controller protocol test information 812. For example, the test controller 810 may generate JTAG protocol test information 828a-b based on the controller protocol test information 812.

The test controller 810 may be used to control the test circuitry 804 (including the boundary scan register 834 and/or scan chain(s) 846, for example). In the example illustrated in FIG. 8, the test controller 810 is coupled to multiplexer A 838a. The test controller 810 provides JTAG protocol test information 828a-b (and/or test information 806g-h) in order to perform one or more tests. For instance, the test controller 810 may provide JTAG protocol test information 828a to multiplexer A 838a. Additionally, the test controller 810 may use JTAG protocol test information 828b to control multiplexer A 838a. For example, the test controller 810 may use some JTAG protocol test information 828b (e.g., an instruction, control signal, etc.) to select JTAG protocol test information 828a (instead of information, if any, from an external route that may have its access blocked 826) as selected JTAG protocol test information 828c that is provided to the test access port (TAP) 824. The selected JTAG protocol test information 828c may in turn be used to generate test information 806a-b. For example, the test controller 810 may “intercept” external information (if any) en-route to the TAP 824 interface and provide JTAG protocol test information 828a (that is based on HSIO protocol test information 818 received by the high-speed input/output (HSIO) interface 816) to generate test information 806a-b instead of external information (if any) en-route to the test access port (TAP) 824.

The boundary scan register 834 and/or test circuitry 804 may perform one or more operations based on the test information 806a-b. For example, the boundary scan register 834 may apply certain bits to particular pins of the integrated circuit 802 and/or the test circuitry 804 may apply the test information 806b. The boundary scan register 834 and/or the test circuitry 804 may generate test results 808a based on the test information 806a-b. The test results 808a may be provided to the test access port (TAP) 824.

Additionally or alternatively, the test controller 810 may perform other tests. For example, the test controller 810 may use some parallel test information 806c-f (from serial test information 806h, for example) to test scan chains 846c-f (based on HSIO protocol test information 818 received by the high-speed input/output (HSIO) interface 816). In one configuration, each of the scan chains 846c-f may include one or more flip-flops that can be tested by providing test information 806c-f. For example, the test controller 810 may provide test information 806h to multiplexer B 838b as a high speed serial data stream. The test controller 810 may also use test information 806g to control multiplexer B 838b in order to decode (e.g., demultiplex) the test information 806h that is provided as a high speed serial data stream. For instance, the test information 806h may comprise an 80 Mbps data stream that is demultiplexed into four sets of test information 806c-f as four 20 Mbps data streams.

The scan chains 846c-f may produce test results 808c-f that may be provided to the test controller 810. In one configuration, the test results 808c-f may be provided to the test controller 810 in parallel. In another configuration, the test results 808c-f may be combined as a serial data stream 808g that is provided to the test controller 810. For example, the test results 808c-f may be multiplexed into a single serial data stream 808g that is provided to the test controller 810.

The test controller 810 may receive JTAG protocol test results 830 from the test access port (TAP) 824. For example, the test access port (TAP) 824 may provide JTAG protocol test results 830 to the test controller 810 based on the test results 808a received from the boundary scan register 834 and/or test circuitry 804.

The test controller 810 may generate controller protocol test results 814 based on the JTAG protocol test results 830 and/or the test results 808c-f. For example, the test controller 810 may format the JTAG protocol test results 830 and/or the test results 808c-f into controller protocol test results 814. For instance, the test controller 810 may remove JTAG protocol formatting from the JTAG protocol test results and add controller protocol information (e.g., structure) according to a controller protocol. Additionally or alternatively, the test controller 810 may add controller protocol information (e.g., structure) to the test results 808c-f (e.g., data stream 808g) according to a controller protocol. The test controller 810 may provide the controller protocol test results 814 to the high-speed input/output (HSIO) interface 816. In some configurations, the controller protocol test results 814 may be sent as a serial data stream or as multiple parallel data streams.

The high-speed input/output (HSIO) interface 816 may generate HSIO protocol test results 820 based on the controller protocol test results 814. For example, the high-speed input/output (HSIO) interface 816 may format the controller protocol test results 814 into HSIO protocol test results 820 for transmission to a test device. For instance, the high-speed input/output (HSIO) interface 816 may remove controller protocol formatting from the controller protocol test results 814 and add HSIO protocol information and/or may structure the controller protocol test results 814 according to an HSIO protocol (e.g., USB protocols, MDDI protocols, etc.).

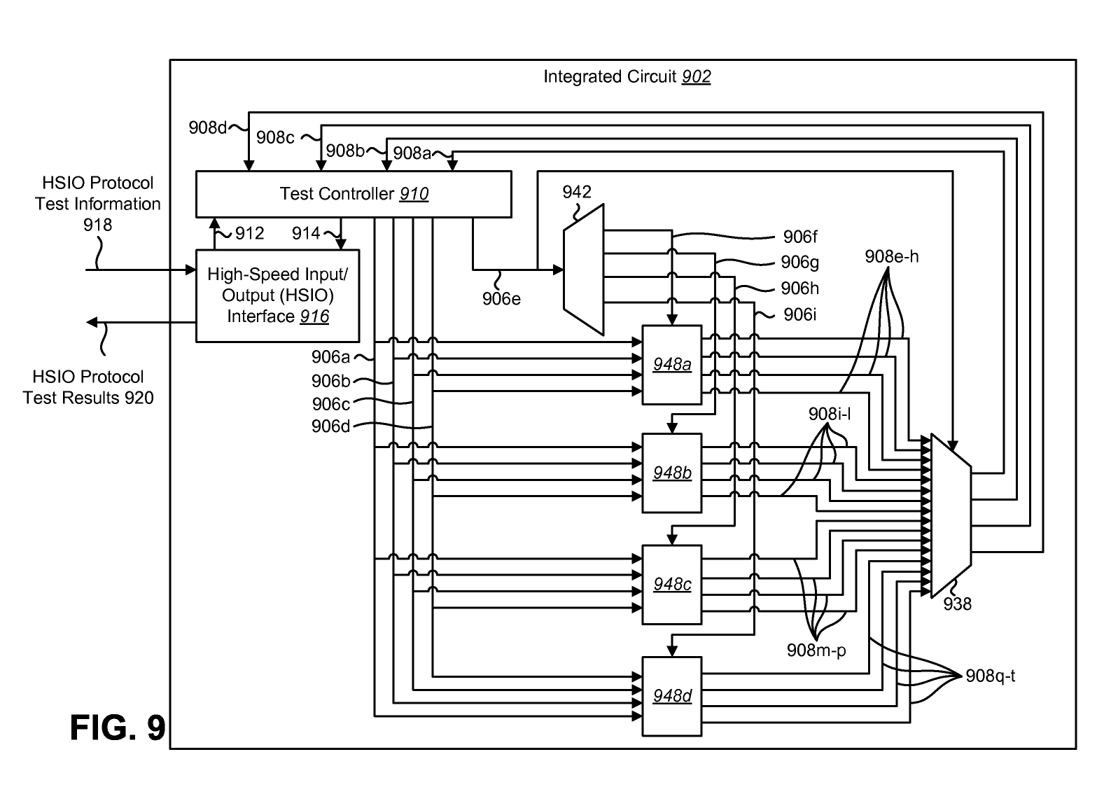

FIG. 9 is a block diagram illustrating another example of an integrated circuit 902 in which testing using a high-speed input/output interface (HSIO) 916 may be implemented. In particular, FIG. 9 illustrates one configuration where registers 948 may be loaded and/or unloaded in parallel in accordance with the systems and methods disclosed herein. In addition to serially loading data to and serially unloading data from registers, parallel data loading may also be supported in some configurations. For instance, a particular register 948 may be selected and test information 906 may be loaded in parallel through a high-speed input/output (HSIO) interface 916. Additionally, the selected register 948 may be read (e.g., unloaded) in parallel.

More detail regarding the example illustrated in FIG. 9 is given hereafter. The integrated circuit 902 includes registers 948a-d (e.g., test circuitry), a test controller 910, a high-speed input/output (HSIO) interface 916, a demultiplexer 942 and a multiplexer 938.

The high-speed input/output (HSIO) interface 916 may receive HSIO protocol test information 918 from an external device (e.g., test device). The HSIO protocol test information 918 may include instructions and/or data for testing. Furthermore, the HSIO protocol test information 918 may be formatted according to HSIO protocols. In some configurations, the high-speed input/output (HSIO) interface 916 may receive the HSIO protocol test information 918 in a parallel format. For instance, the HSIO protocol test information 918 may be received in parallel sets of data, channels or streams.

The high-speed input/output (HSIO) interface 916 may generate controller protocol test information 912 based on the HSIO protocol test information 918. The controller protocol test information 912 may be provided to the test controller 910 in a parallel format in some configurations. The test controller 910 may provide parallel test information 906a-d based on the controller protocol test information 912. For example, the test controller 910 may provide parallel sets of test information 906a-d to registers 948a-d based on the controller protocol test information 912.

The test controller 910 may be used to control the demultiplexer 942, multiplexer 938 and/or registers 948a-d. In the example illustrated in FIG. 9, the test controller 910 is coupled to the demultiplexer 942 and to the multiplexer 938. The test controller 910 provides test information 906e to the demultiplexer 942 and to the multiplexer 938. The test information 906e may be demultiplexed by the demultiplexer 942 to provide test information 906f-i to the registers 948a-d. This test information 906f-i (e.g., control information) may control when a particular register 948a-d may load test information 906a-d from the test controller 910.

The registers 948a-d may provide test results 908e-t to the multiplexer 938. The multiplexer 938 may multiplex (e.g., select) test results 908e-t from the registers to provide (selected) test results 908a-d that are provided to the test controller 910. For example, the multiplexer 938 may select a set of test results 908e-h from a first register 948a, a set of test results 908i-1 from a second register 948b, a set of test results 908m-p from a third register 948c or a set of test results 908q-t from a fourth register 948d based on the test information 906e provided by the test controller 910. The example illustrated in FIG. 9 may be used for testing a graphics or image chip that uses several 4-bit registers 948, for instance.

The test controller 910 may generate controller protocol test results 914 based on the test results 908a-d. For example, the test controller 910 may format the test results 908a-d into controller protocol test results 914. For instance, the test controller 910 may add controller protocol information (e.g., structure) to the test results 908a-d according to a controller protocol. The test controller 910 may provide the controller protocol test results 914 to the high-speed input/output (HSIO) interface 916. In some configurations, the controller protocol test results 914 may be sent as a serial data stream or as multiple parallel data streams.

The high-speed input/output (HSIO) interface 916 may generate HSIO protocol test results 920 based on the controller protocol test results 914. For example, the high-speed input/output (HSIO) interface 916 may format the controller protocol test results 914 into HSIO protocol test results 920 for transmission to a test device. For instance, the high-speed input/output (HSIO) interface 916 may remove controller protocol formatting from the controller protocol test results 914 and add HSIO protocol information and/or may structure the controller protocol test results 914 according to an HSIO protocol (e.g., USB protocols, MDDI protocols, etc.).

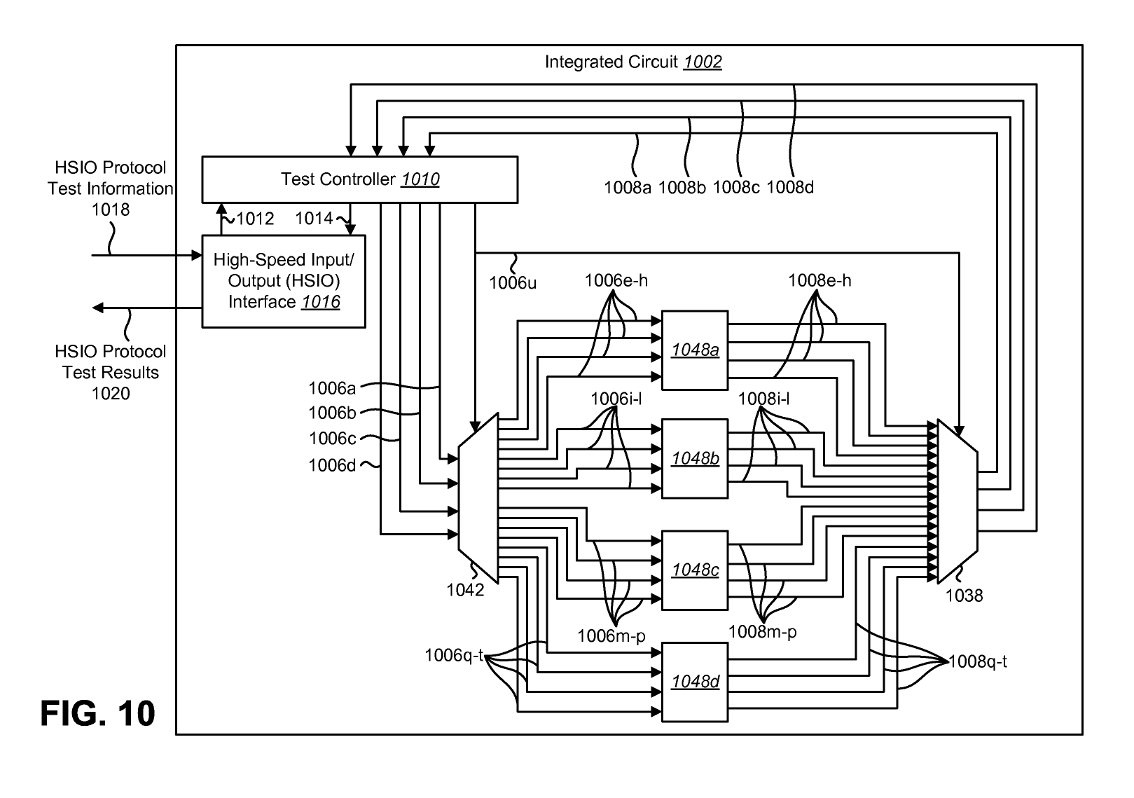

FIG. 10 is a block diagram illustrating another example of an integrated circuit 1002 in which testing using a high-speed input/output interface (HSIO) 1016 may be implemented. In this example, a parallel load of data to all registers 1048 may be enabled. Optionally, identical data may be loaded to all registers 1048 or a particular register 1048 may be loaded with test data while loading the rest of the registers 1048 with a user programmable data (such as all Os, for example). A register 1048 may also be read in parallel in some configurations.

More detail regarding the example illustrated in FIG. 10 is given hereafter. The integrated circuit 1002 includes registers 1048a-d (e.g., test circuitry), a test controller 1010, a high-speed input/output (HSIO) interface 1016, a multiplexer 1038 and a demultiplexer 1042.

The high-speed input/output (HSIO) interface 1016 may receive HSIO protocol test information 1018 from an external device (e.g., test device). The HSIO protocol test information 1018 may include instructions and/or data for testing. Furthermore, the HSIO protocol test information 1018 may be formatted according to HSIO protocols. In some configurations, the high-speed input/output (HSIO) interface 1016 may receive the HSIO protocol test information 1018 in a parallel format. For instance, the HSIO protocol test information 1018 may be received in parallel sets of data, channels or streams.

The high-speed input/output (HSIO) interface 1016 may generate controller protocol test information 1012 based on the HSIO protocol test information 1018. The controller protocol test information 1012 may be provided to the test controller 1010 in a parallel format in some configurations. The test controller 1010 may provide parallel test information 1006a-d based on the controller protocol test information 1012. For example, the test controller 1010 may provide parallel sets of test information 1006a-d to the demultiplexer 1042 based on the controller protocol test information 1012.

The test controller 1010 may be used to control the demulitplexer 1042 and the multiplexer 1038. In the example illustrated in FIG. 10, the test controller 1010 is coupled to the demultiplexer 1042 and to the multiplexer 1038. The test controller 1010 provides test information 1006u to the demultiplexer 1042 and to the multiplexer 1038. The test information 1006u may be used to demultiplex (e.g., route) test information 1006a-d to the registers 1048a-d. For example, the demultiplexer 1042 may demultiplex (e.g., route) the test information 1006a-d into a first set of test information 1006e-h to a first register 1048a, into a second set of test information 1006i-1 to a second register 1048b, into a third set of test information 1006m-p to a third register 1048c and/or into a fourth set of test information 1006q-t to a fourth register 1048d.

The registers 1048a-d may provide test results 1008e-t to the multiplexer 1038. The multiplexer 1038 may multiplex (e.g., select) test results 1008e-t from the registers to provide (selected) test results 1008a-d that are provided to the test controller 1010. For example, the multiplexer 1038 may select a set of test results 1008e-h from the first register 1048a, a set of test results 1008i-1 from a second register 1048b, a set of test results 1008m-p from a third register 1048c or a set of test results 1008q-t from a fourth register 1048d based on the test information 1006u provided by the test controller 1010. The example illustrated in FIG. 10 may be used for testing a graphics or image chip that uses several 4-bit registers 1048, for instance.

The test controller 1010 may generate controller protocol test results 1014 based on the test results 1008a-d. For example, the test controller 1010 may format the test results 1008a-d into controller protocol test results 1014. For instance, the test controller 1010 may add controller protocol information (e.g., structure) to the test results 1008a-d according to a controller protocol. The test controller 1010 may provide the controller protocol test results 1014 to the high-speed input/output (HSIO) interface 1016. In some configurations, the controller protocol test results 1014 may be sent as a serial data stream or as multiple parallel data streams.

The high-speed input/output (HSIO) interface 1016 may generate HSIO protocol test results 1020 based on the controller protocol test results 1014. For example, the high-speed input/output (HSIO) interface 1016 may format the controller protocol test results 1014 into HSIO protocol test results 1020 for transmission to a test device. For instance, the high-speed input/output (HSIO) interface 1016 may remove controller protocol formatting from the controller protocol test results 1014 and add HSIO protocol information and/or may structure the controller protocol test results 1014 according to an HSIO protocol (e.g., USB protocols, MDDI protocols, etc.).

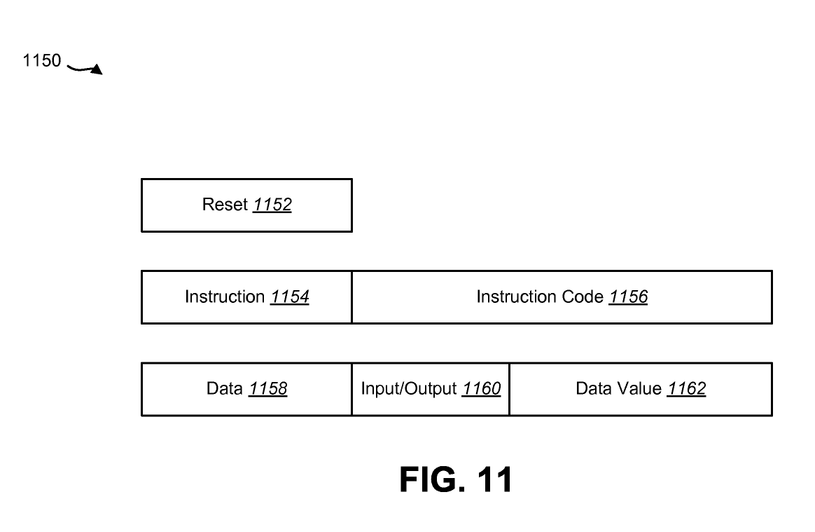

FIG. 11 is a diagram illustrating one example of a controller protocol 1150 that may be used in accordance with the systems and methods disclosed herein. For instance, a test controller 110 and a high-speed input/output (HSIO) interface 116 may communicate based on a controller protocol. For example, a test controller 110 may obtain a clock input from a high-speed input/output (HSIO) interface 116 physical (PHY) layer or from an internal source. A communication channel may then be opened between the test controller 110 and the high-speed input/output (HSIO) interface 116. The test controller 110 and the high-speed input/output (HSIO) interface 116 may communicate with each other based on the controller protocol 1150. For example, controller protocol test information 112 and/or controller protocol test results 114 may be formatted in accordance with the controller protocol 1150.

In the example illustrated in FIG. 11, the controller protocol 1150 may only provide three types of messages that may be sent between the test controller 110 and the high-speed input/output (HSIO) interface 116: a reset message, an instruction message and a data message. The reset message may include a reset indicator 1152. The test controller 110 may set a test access port (TAP) finite state machine (FSM) to idle state after receiving a reset indicator 1152.

An instruction message may include an instruction indicator 1154 and an instruction code 1156. The instruction indicator 1154 may indicate to the test controller 110 that an instruction code 1156 is forthcoming An instruction code 1156 may command the test controller 110 to operate in a particular manner. For example, an instruction code 1156 may indicate that the test controller 110 should advance a TAP FSM to a particular state. In another example, the instruction code 1156 could indicate a particular block/module (e.g., part) of the test circuitry to test.

A data message may include a data indicator 1158, an input/output field 1160 and a data value 1162. The data indicator 1158 may indicate that a period used for input and/or output (e.g., the input/output field 1160) may occur during the message. The input/output field 1160 may specify whether the data value 1162 will be input into the test controller 110 or output from the test controller 110 (such as controller protocol test results 114, for example). The data value 1162 may include controller protocol test information 112 or controller protocol test results 114.

In some configurations, based on whether the communication is an instruction message or data message, the test controller 110 may traverse an FSM sequence (e.g., in a test access port (TAP)) as needed. When an instruction message is received by the test controller 110, for example, the test controller 110 may start from an idle state (in the TAP's FSM) and complete an instruction given by the instruction code 1156. The test controller 110 may then return (the TAP's FSM) to the idle state (thus waiting for any additional command). Additionally, the test controller 110 may output a data value 1162 through the high-speed input/output (HSIO) interface 116 (by using a data message when requested, for example).

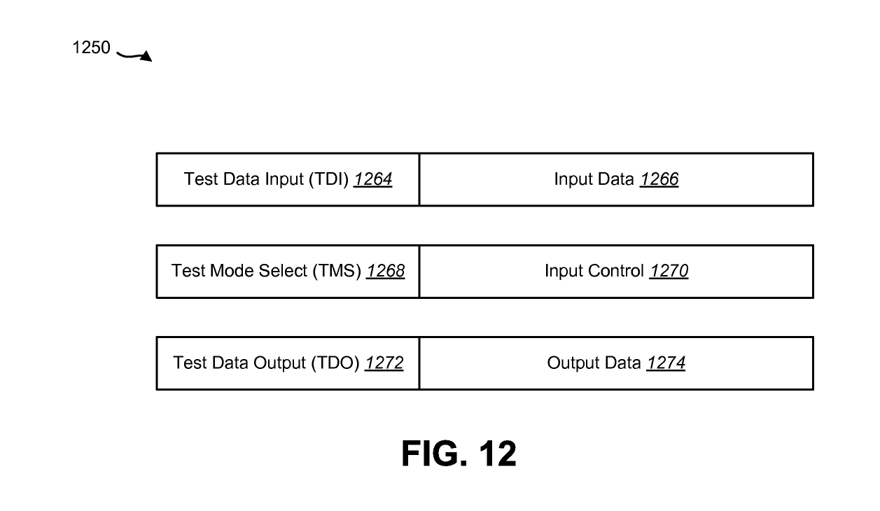

FIG. 12 is a diagram illustrating another example of a controller protocol 1250 that may be used in accordance with the systems and methods disclosed herein. For instance, a test controller 110 and a high-speed input/output (HSIO) interface 116 may communicate based on a controller protocol. For example, a test controller 110 may obtain a clock input from a high-speed input/output (HSIO) interface 116 physical (PHY) layer or from an internal source. A communication channel may then be opened between the test controller 110 and the high-speed input/output (HSIO) interface 116. The test controller 110 and the high-speed input/output (HSIO) interface 116 may communicate with each other based on the controller protocol 1250. For example, controller protocol test information 112 and/or controller protocol test results 114 may be formatted in accordance with the controller protocol 1250.

In the example illustrated in FIG. 12, cycle-by-cycle finite state machine (FSM) (of a test access port (TAP), for example) control may be provided by delivering complete TAP interface signals through the high-speed input/output (HSIO) interface 116 to the test controller 110 using an encoding. For instance, the controller protocol 1250 may include three types of messages: a test data input (TDI) message, a test mode select (TMS) message and a test data output (TDO) message. In other words, the controller protocol test information 112 and/or controller protocol test results 114 may include one or more of the TDI message, the TMS message and the TDO message. In this controller protocol 1250, a test mode select (TMS) sequence to reach a target TAP state is initially delivered. For example, a test mode select (TMS) message may include a test mode select (TMS) indicator 1268 and input control 1270 (information). The TMS indicator 1268 may indicate to a test controller 110 (and to a TAP) that input control 1270 is incoming The input control 1270 may then cause the state of the FSM of the TAP to change.

In a particular state, one or more test data input (TDI) messages and/or test data output (TDO) messages may be used to input data (e.g., test information 106) and/or request data (e.g., test results 108). A TDI message may include a TDI indicator 1264 and input data 1266. A TDO message may include a TDO indicator 1272 and output data 1274. For example, data write and/or read may be performed in a particular state by utilizing test data in (TDI) messages and/or test data out (TDO) messages. A new state transition may then follow by sending a following test mode select (TMS) message. It should be noted that the protocol 1250 illustrated in FIG. 12 may be one approach to embed typical JTAG messages through the high-speed input/output (HSIO) interface 116 and/or through the test controller 110.

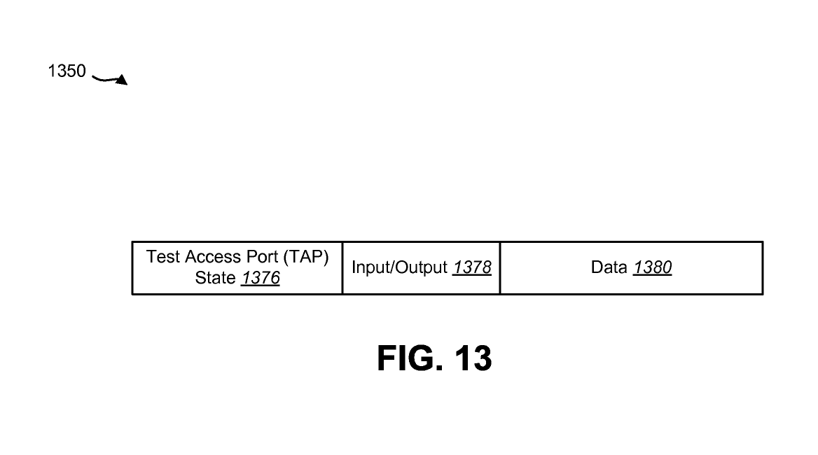

FIG. 13 is a diagram illustrating another example of a controller protocol 1350 that may be used in accordance with the systems and methods disclosed herein. For instance, a test controller 110 and a high-speed input/output (HSIO) interface 116 may communicate based on a controller protocol. For example, a test controller 110 may obtain a clock input from a high-speed input/output (HSIO) interface 116 physical (PHY) layer or from an internal source. A communication channel may then be opened between the test controller 110 and the high-speed input/output (HSIO) interface 116. The test controller 110 and the high-speed input/output (HSIO) interface 116 may communicate with each other based on the controller protocol 1350. For example, controller protocol test information 112 and/or controller protocol test results 114 may be formatted in accordance with the controller protocol 1350.

In the example illustrated in FIG. 13, one message may be used. This message may include a target test access port (TAP) state 1376, an input/output field 1378 and data 1380. Operations (e.g., write and/or read) at a particular state specified by the TAP state 1376 may be embedded in an instruction included in data 1380. The test controller 110 may directly jump to the target state based on the TAP state 1376 (e.g., the encoded state information) in the incoming message and perform data shift in or shift out. The input/output field 1378 may indicate whether data 1380 will be shifted in (as controller protocol test information 112, for example) or whether data 1380 will be shifted out (as controller protocol test results 114, for example).

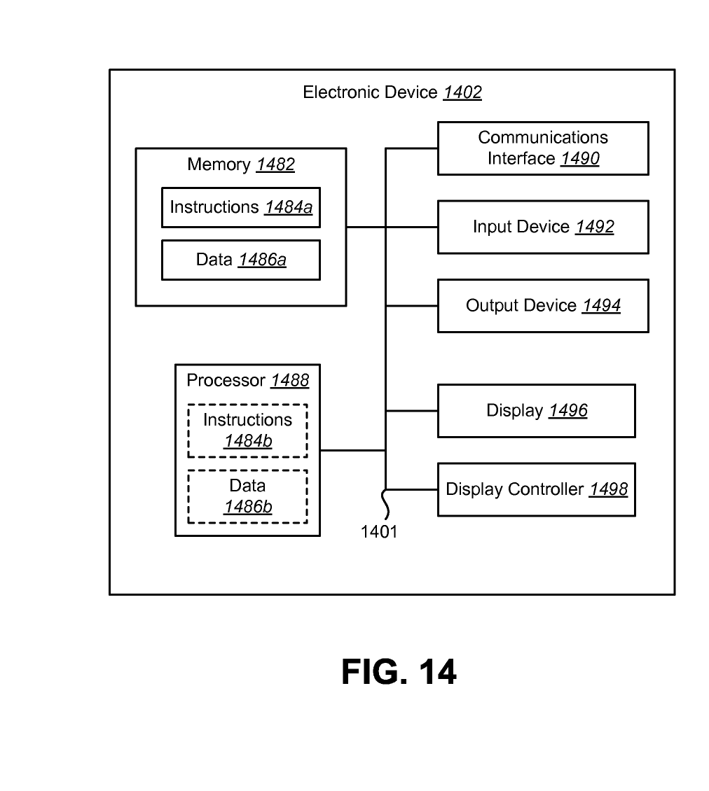

FIG. 14 illustrates various components that may be utilized in an electronic device 1402. The illustrated components may be located within the same physical structure or in separate housings or structures. The electronic device 1402 may be configured similar to the one or more integrated circuits 102, 302, 502, 602, 702, 802, 902, 1002 described previously. The electronic device 1402 includes a processor 1488. The processor 1488 may be a general purpose single- or multi-chip microprocessor (e.g., an ARM), a special purpose microprocessor (e.g., a digital signal processor (DSP)), a microcontroller, a programmable gate array, etc. The processor 1488 may be referred to as a central processing unit (CPU). Although just a single processor 1488 is shown in the electronic device 1402 of FIG. 14, in an alternative configuration, a combination of processors (e.g., an ARM and DSP) could be used.

The electronic device 1402 also includes memory 1482 in electronic communication with the processor 1488. That is, the processor 1488 can read information from and/or write information to the memory 1482. The memory 1482 may be any electronic component capable of storing electronic information. The memory 1482 may be random access memory (RAM), read-only memory (ROM), magnetic disk storage media, optical storage media, flash memory devices in RAM, on-board memory included with the processor, programmable read-only memory (PROM), erasable programmable read-only memory (EPROM), electrically erasable PROM (EEPROM), registers, and so forth, including combinations thereof

Data 1486a and instructions 1484a may be stored in the memory 1482. The instructions 1484a may include one or more programs, routines, sub-routines, functions, procedures, etc. The instructions 1484a may include a single computer-readable statement or many computer-readable statements. The instructions 1484a may be executable by the processor 1488 to implement one or more of the methods 200, 400 described above. Executing the instructions 1484a may involve the use of the data 1486a that is stored in the memory 1482. FIG. 14 shows some instructions 1484b and data 1486b being loaded into the processor 1488 (which may come from instructions 1484a and data 1486a).

The electronic device 1402 may also include one or more communication interfaces 1490 for communicating with other electronic devices. The communication interfaces 1490 may be based on wired communication technology, wireless communication technology, or both. Examples of different types of communication interfaces 1490 include a serial port, a parallel port, a Universal Serial Bus (USB), an Ethernet adapter, an IEEE 1394 bus interface, a small computer system interface (SCSI) bus interface, an infrared (IR) communication port, a Bluetooth wireless communication adapter, an IEEE 802.11 wireless communication adapter and so forth.

The electronic device 1402 may also include one or more input devices 1492 and one or more output devices 1494. Examples of different kinds of input devices 1492 include a keyboard, mouse, microphone, remote control device, button, joystick, trackball, touchpad, lightpen, etc. Examples of different kinds of output devices 1494 include a speaker, printer, etc. One specific type of output device which may be typically included in an electronic device 1402 is a display device 1496. Display devices 1496 used with configurations disclosed herein may utilize any suitable image projection technology, such as a cathode ray tube (CRT), liquid crystal display (LCD), light-emitting diode (LED), gas plasma, electroluminescence, or the like. A display controller 1498 may also be provided, for converting data stored in the memory 1482 into text, graphics, and/or moving images (as appropriate) shown on the display device 1496.

The various components of the electronic device 1402 may be coupled together by one or more buses, which may include a power bus, a control signal bus, a status signal bus, a data bus, etc. For simplicity, the various buses are illustrated in FIG. 14 as a bus system 1401. It should be noted that FIG. 14 illustrates only one possible configuration of an electronic device 1402. Various other architectures and components may be utilized.

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

The term “processor” should be interpreted broadly to encompass a general purpose processor, a central processing unit (CPU), a microprocessor, a digital signal processor (DSP), a controller, a microcontroller, a state machine, and so forth. Under some circumstances, a “processor” may refer to an application specific integrated circuit (ASIC), a programmable logic device (PLD), a field programmable gate array (FPGA), etc. The term “processor” may refer to a combination of processing devices, e.g., a combination of a DSP and a microprocessor, a plurality of microprocessors, one or more microprocessors in conjunction with a DSP core or any other such configuration.

The term “memory” should be interpreted broadly to encompass any electronic component capable of storing electronic information. The term memory may refer to various types of processor-readable media such as random access memory (RAM), read-only memory (ROM), non-volatile random access memory (NVRAM), programmable read-only memory (PROM), erasable programmable read only memory (EPROM), electrically erasable PROM (EEPROM), flash memory, magnetic or optical data storage, registers, etc. Memory is said to be in electronic communication with a processor if the processor can read information from and/or write information to the memory. Memory that is integral to a processor is in electronic communication with the processor.

The terms “instructions” and “code” should be interpreted broadly to include any type of computer-readable statement(s). For example, the terms “instructions” and “code” may refer to one or more programs, routines, sub-routines, functions, procedures, etc. “Instructions” and “code” may comprise a single computer-readable statement or many computer-readable statements.

The functions described herein may be implemented in software or firmware being executed by hardware. The functions may be stored as one or more instructions on a computer-readable medium. The terms “computer-readable medium” or “computer-program product” refers to any non-transitory tangible storage medium that can be accessed by a computer or a processor. By way of example, and not limitation, a computer-readable medium may comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Disk and disc, as used herein, includes compact disc (CD), laser disc, optical disc, digital versatile disc (DVD), floppy disk and Blu-ray® disc where disks usually reproduce data magnetically, while discs reproduce data optically with lasers.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

Further, it should be appreciated that modules and/or other appropriate means for performing the methods and techniques described herein, such as those illustrated by FIG. 2 and FIG. 4, can be downloaded and/or otherwise obtained by a device. For example, a device may be coupled to a server to facilitate the transfer of means for performing the methods described herein. Alternatively, various methods described herein can be provided via a storage means (e.g., random access memory (RAM), read only memory (ROM), a physical storage medium such as a compact disc (CD) or floppy disk, etc.), such that a device may obtain the various methods upon coupling or providing the storage means to the device.

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. An integrated circuit configured for testing, comprising:
a high-speed input/output interface;
a test controller coupled to the high-speed input/output interface; and
test circuitry coupled to the test controller, wherein the test controller controls the test circuitry based on controller protocol test information from the high-speed input/output interface.

2. The integrated circuit of claim 1, further comprising a test access port coupled to the test controller and to the test circuitry.

3. The integrated circuit of claim 2, wherein the high-speed input/output interface formats high-speed input/output protocol test information into the controller protocol test information, and wherein the test controller formats the controller protocol test information into joint test action group protocol test information that is provided to the test access port to control the test circuitry.

4. The integrated circuit of claim 2, wherein the test controller formats joint test action group protocol test results into controller protocol test results, and wherein the high-speed input/output interface formats the controller protocol test results into high-speed input/output protocol test results.

5. The integrated circuit of claim 2, wherein a test access port interface signal is intercepted before the test access port.

6. The integrated circuit of claim 2, wherein test control and data signals provided by the test access port are intercepted after the test access port.

7. The integrated circuit of claim 2, wherein the test controller performs a test on a part of test circuitry that is not accessed through the test access port.

8. The integrated circuit of claim 1, wherein the controller protocol test information includes at least one of a group consisting of a reset message, an instruction message and a data message.

9. The integrated circuit of claim 1, wherein the controller protocol test information includes at least one of a group consisting of a test data input message, a test mode select message and a test data output message.

10. The integrated circuit of claim 1, wherein the controller protocol test information includes a message that includes a target test access port state, an input/output field and data.

11. The integrated circuit of claim 1, wherein the high-speed input/output interface is a universal serial bus (USB) interface.

12. The integrated circuit of claim 1, wherein the high-speed input/output interface is a mobile display digital interface (MDDI).

13. The integrated circuit of claim 1, wherein the test circuitry is at least one of a group consisting of a boundary scan register, a scan chain, a register and memory.

14. The integrated circuit of claim 1, wherein the controller protocol test information is in a parallel format.

15. The integrated circuit of claim 1, wherein the controller protocol test information is in a serial format.

16. The integrated circuit of claim 1, wherein the test controller is separate from the high-speed input/output interface.

17. A method for testing an integrated circuit, comprising:
receiving high-speed input/output protocol test information at a high-speed input/output interface;
generating controller protocol test information based on the high-speed input/output protocol test information;
providing the controller protocol test information to a test controller; and
controlling test circuitry based on the controller protocol test information from the high-speed input/output interface.

18. The method of claim 17, wherein the integrated circuit comprises a test access port coupled to the test controller and to the test circuitry.

19. The method of claim 18, wherein generating the controller protocol test information comprises formatting the high-speed input/output protocol test information into the controller protocol test information, and wherein the method further comprises formatting the controller protocol test information into joint test action group protocol test information that is provided to the test access port to control the test circuitry.

20. The method of claim 18, further comprising formatting joint test action group protocol test results into controller protocol test results; and formatting the controller protocol test results into high-speed input/output protocol test results.

21. The method of claim 18, further comprising intercepting a test access port interface signal before the test access port.

22. The method of claim 18, further comprising intercepting test control and data signals provided by the test access port after the test access port.

23. The method of claim 18, further comprising performing a test on a part of test circuitry that is not accessed through the test access port.

24. The method of claim 17, wherein the controller protocol test information includes at least one of a group consisting of a reset message, an instruction message and a data message.

25. The method of claim 17, wherein the controller protocol test information includes at least one of a group consisting of a test data input message, a test mode select message and a test data output message.

26. The method of claim 17, wherein the controller protocol test information includes a message that includes a target test access port state, an input/output field and data.

27. The method of claim 17, wherein the high-speed input/output interface is a universal serial bus (USB) interface.

28. The method of claim 17, wherein the high-speed input/output interface is a mobile display digital interface (MDDI).

29. The method of claim 17, wherein the test circuitry is at least one of a group consisting of a boundary scan register, a scan chain, a register and memory.

30. The method of claim 17, wherein the controller protocol test information is in a parallel format.

31. The method of claim 17, wherein the controller protocol test information is in a serial format.

32. The method of claim 17, wherein the test controller is separate from the high-speed input/output interface.

33. A computer-program product for testing an integrated circuit, comprising a non-transitory tangible computer-readable medium having instructions thereon, the instructions comprising:
code for causing an electronic device to receive high-speed input/output protocol test information at a high-speed input/output interface; code for causing the electronic device to generate controller protocol test information based on the high-speed input/output protocol test information;
code for causing the electronic device to provide the controller protocol test information to a test controller; and
code for causing the electronic device to control test circuitry based on the controller protocol test information from the high-speed input/output interface.

34. The computer-program product of claim 33, wherein the integrated circuit comprises a test access port coupled to the test controller and to the test circuitry.

35. The computer-program product of claim 34, wherein the code for causing the electronic device to generate the controller protocol test information comprises code for causing the electronic device to format the high-speed input/output protocol test information into the controller protocol test information, and wherein the instructions further comprise code for causing the electronic device to format the controller protocol test information into joint test action group protocol test information that is provided to the test access port to control the test circuitry.

36. The computer-program product of claim 34, wherein the instructions further comprise code for causing the electronic device to format joint test action group protocol test results into controller protocol test results; and code for causing the electronic device to format the controller protocol test results into high-speed input/output protocol test results.

37. An apparatus for testing an integrated circuit, comprising:
means for receiving high-speed input/output protocol test information;
means for generating controller protocol test information based on the high-speed input/output protocol test information;
means for providing the controller protocol test information; and
means for controlling test circuitry based on the controller protocol test information.

38. The apparatus of claim 37, wherein the integrated circuit comprises additional means for testing the test circuitry.

39. The apparatus of claim 37, wherein the means for generating the controller protocol test information comprises means for formatting the high-speed input/output protocol test information into the controller protocol test information, and wherein the apparatus further comprises means for formatting the controller protocol test information into joint test action group protocol test information that is provided to control the test circuitry.

40. The apparatus of claim 37, wherein the apparatus further comprises means for formatting joint test action group protocol test results into controller protocol test results; and means for formatting the controller protocol test results into high-speed input/output protocol test results.
